(19) United States
(12) Patent Application Publication
(10) Pub. No.: US 2025/0112168 A1
(43) Pub. Date: Apr. 3, 2025

(54) HYBRID BONDING WITH EMBEDDED ALIGNMENT MARKERS

(71) Applicant: Intel Corporation, Santa Clara, CA (US)

(72) Inventors: Omkar G. Karhade, Chandler, AZ (US); Nitin A. Deshpande, Chandler, AZ (US); Gwang-Soo Kim, Portland, OR (US); Harini Kilambi, Portland, OR (US); Han Ju Lee, Hillsboro, OR (US)

(73) Assignee: Intel Corporation, Santa Clara, CA (US)

(21) Appl. No.: 18/477,813

(22) Filed: Sep. 29, 2023

(51) Int. Cl. H01L 23/544; H01L 23/00; H01L 23/522; H01L 23/538; H01L 25/065

(52) U.S. Cl. CPC H01L 23/544; H01L 23/5226; H01L 23/5383; H01L 24/80; H01L 25/0655; H01L 24/08; H01L 2223/54426; H01L 2224/08225; H01L 2224/8013

(57) ABSTRACT

Alignment markers are created on a carrier wafer prior to attachment of integrated circuit dies to the carrier wafer. The alignment markers can be used in aligning integrated circuit dies to the carrier wafer during attachment of the integrated circuit dies to the carrier wafer. A reconstituted wafer can be created from the integrated circuit dies attached to the carrier wafer and the alignment markers are part of the reconstituted wafer. The alignment markers can further be used to align a wafer bonding layer to the reconstituted wafer. The wafer bonding layer can be used in attaching the reconstituted wafer to an interposer, another wafer, or another microelectronic structure. The alignment markers are located outside an outer lateral boundary of the integrated circuit dies (such as between integrated circuit dies) and are not connected to any metal lines in the integrated circuit dies in the reconstituted wafer.

### BACKGROUND

Hybrid bonding can comprise bonding dielectric and metal regions on a first surface to dielectric and metal regions on a second surface, resulting in dielectric-to-dielectric and metal-to-metal bonds. Hybrid bonding can be used for wafer-to-wafer, die-to-wafer, die-to-die, and other types of bonding (e.g., die-to-interposer).

### BRIEF DESCRIPTION OF THE DRAWINGS

FIG. 1A is a cross-sectional view of an example microelectronic structure comprising a carrier wafer after formation of a bonding layer on the carrier wafer.

FIG. 1B is a cross-sectional view of the microelectronic structure after formation of an alignment marker layer on the carrier wafer.

FIG. 1C is a cross-sectional view of the microelectronic structure after patterning of the alignment marker layer.

FIG. 1D is a cross-sectional view of the microelectronic structure after attachment of integrated circuit dies to the carrier wafer.

FIG. 1E is a cross-sectional view of the microelectronic structure after formation of a liner layer and an oxide layer on the microelectronic structure and attachment of a lid to the microelectronic structure.

FIG. 1F is a cross-sectional view of the microelectronic structure after removal of the carrier wafer.

FIG. 1G is a cross-sectional view of the reconstituted wafer after formation of a wafer bonding layer to the reconstituted wafer.

FIG. 1H a cross-sectional view of the reconstituted wafer 100 after attachment of an interposer to the reconstituted wafer.

FIG. 1I is a cross-sectional view of the microelectronic structure after thinning of the substrate region to expose vias and formation of conductive contacts on the exposed vias.

FIG. 1J is a cross-sectional view of an example integrated circuit component comprising the microelectronic structure of FIG. 1I.

FIG. 2 is a top view of an example alignment marker.

FIG. 3 is a top view of the microelectronic structure after attachment of integrated circuit dies to the carrier wafer.

FIG. 4 is a cross-sectional view of an example microelectronic structure comprising a first reconstituted wafer attached to a second reconstituted wafer.

FIG. 5 illustrates an example microelectronic structure comprising a reconstituted wafer attached to an interposer without an intervening wafer bonding layer.

FIG. 6 is an example method of fabricating a microelectronic structure comprising embedded alignment markers.

FIG. 7 is a top view of a wafer and dies that may be included in any of the microelectronic assemblies or structures disclosed herein.

FIG. 8 is a cross-sectional side view of an integrated circuit device that may be included in any of the microelectronic assemblies or structures disclosed herein.

FIG. 9 is a cross-sectional side view of an integrated circuit device assembly that may include any of the microelectronic assemblies or structures disclosed herein.

FIG. 10 is a block diagram of an example electrical device 1000 that may include one or more of the microelectronic assemblies or structures disclosed herein.

### DETAILED DESCRIPTION

Advanced integrated circuit components can comprise heterogenous integrated circuit dies that vary by functionality, semiconductor processing technology node, size, bond pad design (e.g., size, pitch, arrangement) and/or other parameters. The assembly of such integrated circuit components can involve the fabrication of dies on separate wafers, transferring known-good dies (KGDs) from the original wafers to a carrier wafer, forming a reconstituted wafer that includes the transferred die, and attaching an interposer, substrate, or other microelectronic structure to the reconstituted wafer. Hybrid bonding can be used for bonding known-good dies to a carrier wafer and for attaching an interposer, substrate, or other microelectronic structure to a reconstituted wafer containing the known-good die. Hybrid bonding can comprise bonding dielectric and metal regions of a first surface to dielectric and metal regions of a second surface, resulting in dielectric-to-dielectric and metal-to-metal bonds. Hybrid bonding can result in structures having a smaller dimension relative to structures that do not utilize hybrid bonding as they do not rely on balls, bumps, or other structures that protrude from a surface being bonded to enable bonding of two surfaces.

Reconstituted wafers provide benefits in addition to enabling heterogeneous integrated circuit dies to be incorporated into a single integrated circuit component. For example, reconstituted wafers can enable high-yield hybrid bonds as a bonding layer can be added to a reconstituted wafer that provides a high-quality bonding layer. One challenge to adding a bonding layer to a reconstituted wafer is how to align the bonding layer to the reconstituted dies (the integrated circuit dies that are part of the reconstituted wafer). Typically, there is no frame for the integrated circuit die pattern that is repeated on the reconstituted wafer that can be used for aligning a wafer bonding layer to a reconstituted wafer. Further, layer alignment methods typically used in integrated circuit manufacturing are unavailable for aligning a bonding layer to a reconstituted wafer as the space between the reconstituted dies is devoid of features or structures that could be used for alignment. This is also a challenge for the direct bonding of a reconstituted wafer to another wafer or microelectronic structure (without a wafer bonding layer between the reconstituted wafer and the other wafer). This alignment challenge further extends to the alignment of integrated circuit dies to a carrier wafer.

Existing approaches to solving these alignment challenges include adding alignment markers to reconstituted die. This approach is undesirable as the alignment markers occupy value die real estate, especially in instances where the alignment makers are large (e.g., about 100 microns by two millimeters). In another existing approach, alignment markers are embedded in the carrier wafer. This can enable the alignment of integrated circuit dies to a carrier wafer during reconstituted wafer formation, but it can complicate the carrier wafer removal process if the alignment markers are desired to be left behind after carrier wafer removal for use during alignment of a wafer bonding layer to the reconstituted wafer during wafer bonding layer-to-reconstituted wafer alignment. Further, planarization of the wafer bonding layer after formation of the wafer bonding layer may be complicated due to the presence of the alignment markers left behind after carrier wafer removal as the alignment markers can create topography on the surface of the reconstituted wafer on which the wafer bonding layer is formed.

Disclosed herein is a hybrid bonding architecture in which alignment markers are formed on the surface of a carrier wafer and left embedded in the reconstituted wafer after carrier wafer removal. The alignment markers are located in the space between reconstituted dies and are not conductively connected to any metal lines in the reconstituted dies. The alignment markers can be used, for example, for alignment of reconstituted dies to a carrier wafer (die-to-wafer alignment), alignment of the wafer bonding layer to the reconstituted die, alignment of the reconstituted wafer to another wafer or other microelectronic structure (wafer-to-wafer alignment), and alignment registration.

The hybrid bonding architecture disclosed herein has at least the following advantages. First, the alignment markers do not consume valuable integrated circuit die area. Second, die misalignment error does not interfere with the alignment of a wafer bonding layer. The alignment markers embedded in the reconstituted wafer function as a pseudo-frame for the wafer bonding layer, enabling wafer bonding layer alignment. Third, by enabling reconstituted dies to be aligned with the wafer bonding layer, a finer bond pad pitch in the integrated circuit dies and wafer bonding layer can be realized due to not having to account for misalignment between the reconstituted dies and the wafer bonding layer.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or in any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous.

Terms modified by the word “substantially” include arrangements, orientations, spacings, or positions that vary slightly from the meaning of the unmodified term. For example, the portion of a first layer or feature that is substantially perpendicular to a second layer or feature can include a first layer or feature that is +/−20 degrees from a second layer or feature, a first surface that is substantially parallel to a second surface can include a first surface that is within several degrees of parallel from the second surface, and a layer that is substantially planar can include layers that comprise some dishing, bumps, or other non-planar features resulting from processing variations and/or limitations. Further, a first layer that is substantially coplanar with another second layer includes first layers that are offset by a small amount due to processing variations and limitations, and a layer that substantially fills the volume includes layers that fill a volume except for small voids and other gaps in the layer. Moreover, a stated value for a dimension, feature, or characteristic qualified by the term “about” includes values within +/−10% of the stated value. Similarly, a stated range of values for a dimension, feature, or characteristic includes values within 10% of the listed upper and lower values for the range.

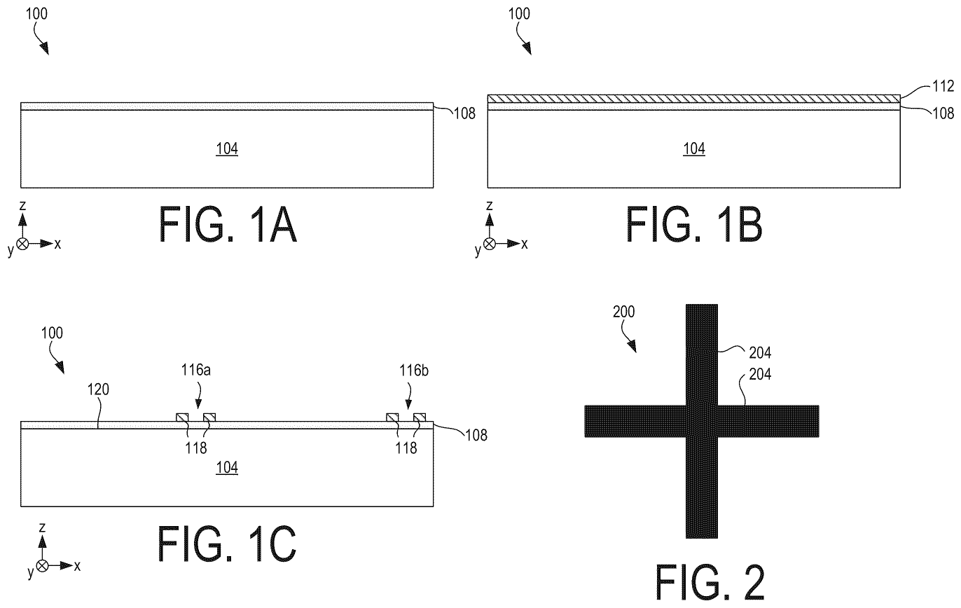

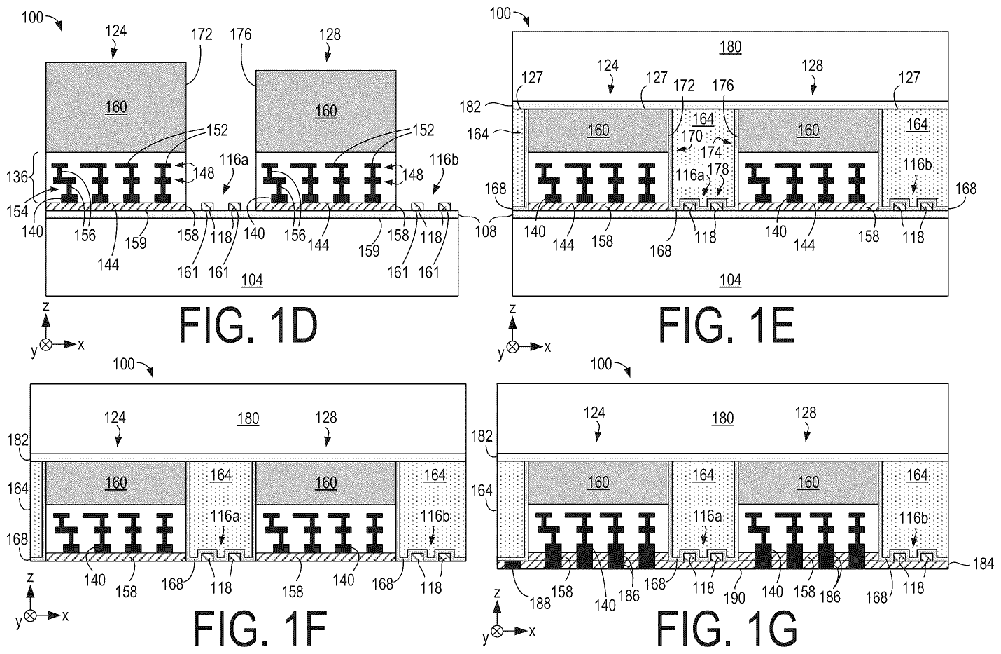

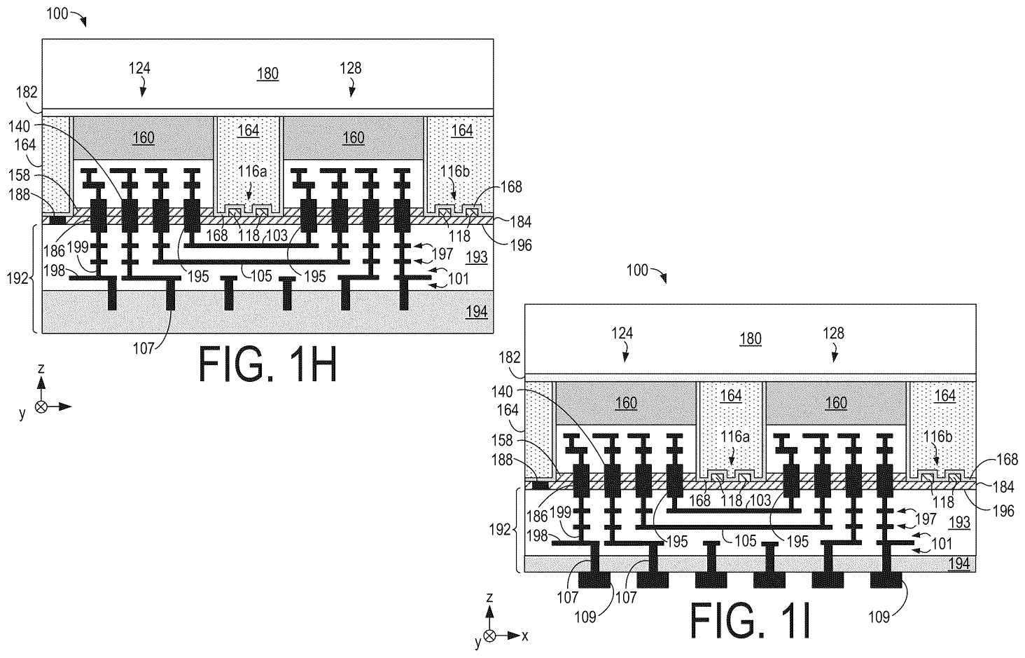

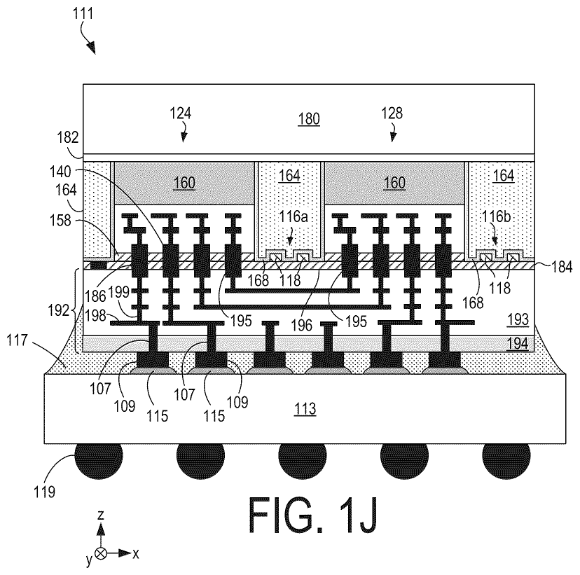

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. For example, with reference to FIG. 1D, the integrated circuit dies 124 and 128 are located on the carrier wafer 104 (with an intervening die bonding layer 108).

As used herein, the phrase “positioned between” in the context of a first layer or component positioned between a second layer or component and a third layer or component refers to the first layer or component being directly physically attached to the second and/or third parts or components (no layers or components between the first and second layers or components or the first and third layers or components) or physically attached to the second and/or third layers or components via one or more intervening layers or components. For example, with reference to FIG. 1E, portions of the liner layer 168 are positioned between the oxide layer 164 and sidewalls 172 and 176 of integrated circuit dies 124 and 128, respectively.

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “integrated circuit component” refers to a packaged or unpackaged integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims.

FIGS. 1A-1J illustrate cross-sectional views of an example simplified process of fabricating a heterogeneous multi-die integrated circuit component comprising embedded alignment markers. Any of the fabrication methods or processes described herein, including method 600, may be performed using any suitable microelectronic fabrication techniques. For example, film deposition-such as depositing layers, filling (backfilling) portions of layers (e.g., filling removed portions of layers or removed layers), and filling via or contact openings—may be performed using any suitable deposition techniques, including, for example, chemical vapor deposition (CVD), metalorganic chemical vapor deposition (MOCVD), molecular beam epitaxy (MBE), atomic layer deposition (ALD), sputtering and/or physical vapor deposition (PVD). Moreover, layer patterning—such as dielectric or metal layer patterning—may be performed using any suitable techniques, such as photolithography-based patterning and etching (e.g., dry etching or wet etching). Furthermore, planarization of layers may be performed by using any suitable planarization technique, such as chemical-mechanical polishing (CMP).

FIGS. 1A-1D are cross-sectional views of an example manufacturing process to create alignment markers on a carrier wafer. FIG. 1A is a cross-sectional view of an example microelectronic structure 100 comprising a carrier wafer 104 after formation of a bonding layer 108 on the carrier wafer 104. As the bonding layer 108 is attached to the carrier wafer 104 via fusing of the bonding layer 108 to the surface of the carrier wafer 104, the carrier wafer 104 can be referred to as a fusion bond carrier wafer. In any of the embodiments described or referenced herein, the carrier wafer 104 can be a wafer, panel, or other structure that can provide mechanical support to integrated circuit dies. In any of the embodiments described or referenced herein, the carrier wafer 104 can comprise silicon, glass (e.g., amorphous solid glass, such as aluminosilicate, borosilicate, alumino-borosilicate, silica, and fused silica), sapphire, plastic, silicon carbide (SiC), gallium arsenide (GaAs) or other suitable material. In any of the embodiments described or referenced herein, the bonding layer 108 can comprise a dielectric, such as an oxide, nitride, or other suitable dielectric. For example, the bonding layer 108 can comprise silicon and oxygen (e.g., SiOₓ, silicon dioxide (SiO₂)), silicon and nitrogen, (e.g., SiₓN_{y}, Si₃N₄)) or silicon, carbon, and nitrogen (e.g., SiCN). In some embodiments, the thickness of the bonding layer 108 can be about two microns. The bonding layer 108 can have a thickness different than two microns in other embodiments.

FIG. 1B is a cross-sectional view of the microelectronic structure 100 after formation of an alignment marker layer 112 on the carrier wafer 104. The alignment marker layer 112 can comprise a metal (such as copper, titanium, or tantalum), a dielectric (such as SiOₓ, SiₓN_{y}, alumina (e.g., Al₂O₃. a material comprising aluminum and oxygen), a metal and a dielectric, or another suitable material or combination of materials.

FIG. 1C is a cross-sectional view of the microelectronic structure 100 after patterning of the alignment marker layer 112. Patterning of the alignment marker layer 112 can be performed by a photolithography process, resulting in patterned alignment markers 116 (116a, 116b) that protrude from a surface 120 of the carrier wafer 104. Although the alignment markers illustrated in FIG. 1C can be characterized by the presence of material (e.g., features protruding from the surface 120 of the carrier wafer and present in a reconstituted wafer), in other embodiments, alignment markers can be characterized by the absence of material. For example, an alignment marker can be one or more channels or trenches in a layer, such as in a layer of metal.

An alignment marker 116 is a structure that comprises one or more lines, traces, or portions 118 (or channels or trenches) and can be any shape or combination of shapes. The cross-sectional views of the alignment markers 116 illustrated in FIG. 1A comprise two alignment marker traces 118. In some embodiments, the thickness of the alignment marker 116 portions (or the thickness of an alignment marker trench or channel) can be in the range of about 50 nanometers to five microns. The thickness of the alignment marker 116 portions can be less than 50 nanometers or greater than 5 microns in other embodiments.

FIG. 2 is a top view of an example alignment marker. The alignment marker 200 comprises a pair of orthogonally intersecting traces 204, making a cross shape. In other embodiments, alignment markers, whether characterized by the presence or absence of material, can comprise other shapes, such as a circle, square, rectangle, one or more lines, or combinations thereof.

FIG. 1D is a cross-sectional view of the microelectronic structure 100 after attachment of integrated circuit dies to the carrier wafer. A first integrated circuit die 124 and a second integrated circuit die 128 are attached to the carrier wafer by die bonding layers 158. The individual die bonding layers 158 are attached to a surface 144 of one of the integrated circuit dies (124, 128) that is proximal to the carrier wafer 104. The integrated circuit dies 124 and 128 are arranged laterally (that is, they are arranged in the x-y plane and do not vertically overlap) and are spaced laterally from each other. The alignment markers 116 can be used in aligning the integrated circuit dies 124 and 128 to the carrier wafer 104 during die placement.

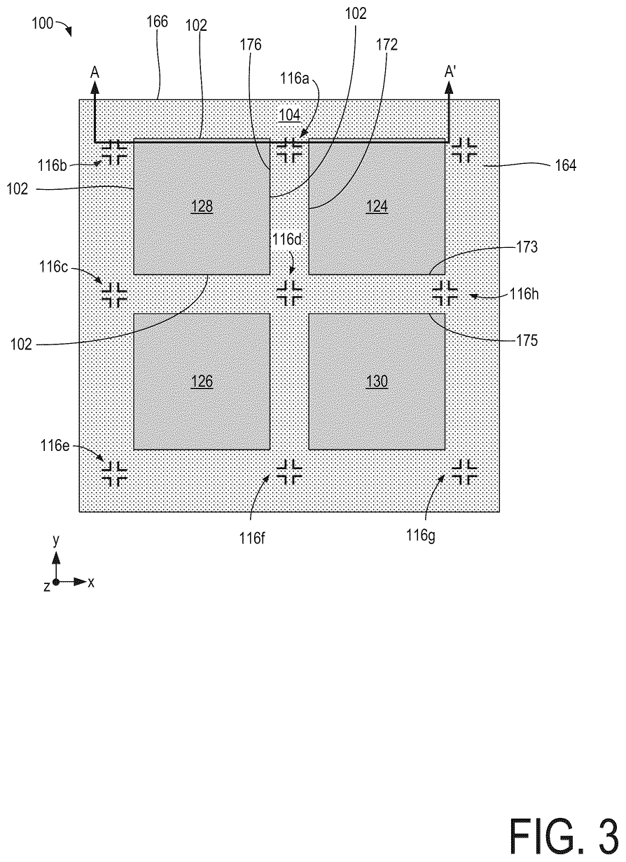

FIG. 3 is a top view of the microelectronic structure 100 after attachment of integrated circuit dies to the carrier wafer 104. The cross-sectional view illustrated in FIG. 1D is taken along the line A-A′ in FIG. 3. In addition to integrated circuit dies 124 and 128, the microelectronic structure 100 comprises integrated circuit dies 126 and 130 attached to the carrier wafer 104. Each die has an outer lateral boundary that encloses the extent to which each die extends in the x-y plane. For example, integrated circuit die 128 has an outer lateral boundary 102. FIG. 3 illustrates nine alignment markers 116. The alignment markers reside within an outer lateral boundary 166 of the oxide layer 164. The alignment markers 116 can be positioned at least partially between physically adjacent die. For example, alignment marker 116a resides in the volume between sidewall 172 of integrated circuit die 124 and sidewall 176 of integrated circuit die 128, and alignment marker 116h resides partially in the volume between sidewall 173 of integrated circuit die 124 and sidewall 175 of integrated circuit die 130. The alignment markers can further reside at positions proximal to corners of an integrated circuit die, such as alignment markers 116c, 116d, 116e, and 116f, which are proximal to the corners of integrated circuit die 126. Alignment markers can also be located between the outer lateral boundary of an integrated circuit die and within the outer lateral boundary 166 of the oxide layer 164, such as alignment markers 116e and 116g. In some embodiments, the space between physically adjacent integrated circuit dies is in the range of about 20 microns to 100 millimeters. 100 microns or less. In some embodiments, the alignment markers occupy a lateral area of about 10,000 square microns or less. In some embodiments, the alignment markers can be about 100 microns by three millimeters.

Returning to FIG. 1D, the alignment markers 116 can be used to align integrated circuit dies to the carrier wafer 104 during attachment of the dies to the carrier wafer 104. Attachment of an integrated circuit die to a carrier wafer can utilize one or more alignment markers located on the surface of the carrier wafer, and integrated circuit die can be placed on the carrier wafer surface relative to alignment markers in any manner. That is, a die can be placed with one or more alignment markers located off one or more of the die's corners, with one or more markers located between integrated dies, etc. The arrangement of alignment markers illustrated in FIG. 3 is just one possible alignment marker arrangement. In other embodiments, the arrangement of alignment markers can differ from that shown in FIG. 3, and more or fewer alignment markers can be used than shown in FIG. 3. In some embodiments, the integrated circuit dies 124 and 128 are attached to the carrier wafer 104 by forming of the die bonding layers 158 on the carrier wafer 104 and then attaching the dies 124 and 128 to the die bonding layers 158, using the alignment markers 116 for aligning the dies 124 and 128 to the carrier wafer 104. If alignment markers are not used for aligning the die bonding layers 158 to the carrier wafer 104, there may be some misalignment between the die bonding layers 158 and the integrated circuit dies 124 and 128.

The integrated circuit dies 124 and 128 comprise metallization regions 136 that comprise conductive contacts 140 located on surfaces 144 of the integrated circuit dies 124 and 128, metal layers 148 comprise metal lines 152, and vias 156. Each via 156 connects metal lines 152 of different metal layers or a metal line 152 to a conductive contact 140. The dies 124 and 128 further comprise substrate regions 160 that can comprise transistors and/or other active or passive devices. The alignment markers 116 are vertically aligned with the die bonding layers 158. That is, a surface 161 of the alignment markers 116, which can comprise multiple surfaces in embodiments where the alignment marker comprises multiple portions are substantially coplanar with a surface 159 of the die bonding layer 158 (the surface of the die bonding layer 158 proximal to the carrier wafer 104).

In some embodiments, the metal layers 148 can be separated by inter-layer dielectrics (ILD) 154. The ILDs 154 can comprise a suitable nitride or oxide, such as silicon nitride (e.g., SiₓN_{y}, Si₃N₄), silicon dioxide (e.g., Siₓ, SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen).

In any of the embodiments described or referenced herein, the vias 156 can comprise tungsten, titanium, copper, aluminum, or another suitable conductive material, and the metal lines 152 and conductive contacts 140 can comprise copper, aluminum, cobalt, ruthenium, alloys of these materials, or another suitable conductive material. In any of the embodiments described or referenced herein, the vias 156 and metal lines 152 can comprise one or more barrier layers comprising tantalum, tantalum nitride (TaN, a material comprising tantalum and nitrogen), titanium, or another suitable material.

In any of the embodiments described or referenced herein, the substrate regions 160 may include, for example, a crystalline substrate formed using a bulk silicon or a silicon-on-insulator (SOI) substructure. In some embodiments, the die substrate regions 160 may be formed using alternative materials, which may or may not be combined with silicon, that include, but are not limited to, germanium. Further materials classified as group II-VI, III-V, or IV may also be used to form the die substrate regions 160. Although a few examples of materials from which the die substrate regions 160 may be formed are described here, any material that may serve as a foundation for an integrated circuit device may be used.

In any of the embodiments described or referenced herein, the die bonding layers 158 can comprise silicon and oxygen (e.g., SiOₓ, SiO₂), silicon and nitrogen (e.g., Si₃N₄, SiₓN_{y}), silicon, carbon, and nitrogen (e.g., SiCN), or another suitable material.

FIG. 1E is a cross-sectional view of the microelectronic structure 100 after formation of a liner layer and an oxide layer on the microelectronic structure 100 and attachment of a lid to the microelectronic structure 100. A conformal liner layer 168 is formed on the microelectronic structure 100 and covers the integrated circuit dies 124 and 128. Portions of the liner layer 168 cover sidewalls of the integrated circuit die 124 and 128 and the alignment markers 116. For example, a liner layer portion 170 covers sidewall 172 of the integrated circuit die 124, a liner layer portion 174 covers sidewall 176 of the integrated circuit die 126, and liner layer portion 178 covers the alignment marker 116a. The liner layer 168, as formed, also covers the surfaces of the integrated circuit dies 124 and 128 that are distal from the carrier wafer 104 after formation of the liner layer 168, but those portions of the liner layer 168 are removed before formation of a lid bonding layer 182).

After formation of the liner layer 168, an oxide layer 164 is formed on the liner layer 168. The oxide layer 164 substantially fills the volumes between the integrated circuit dies 124 and 128 and can extend past the outer lateral boundary of the integrated circuit dies 124 and 128. The oxide layer 164 covers the alignment markers 116a and 116b. After formation of the oxide layer 164, the liner layer portion 170 is positioned between the oxide layer 164 and the sidewall 172, the liner layer portion 174 is positioned between the oxide layer 164 and the sidewall 176, and the liner layer portion 178 is positioned between the oxide layer 164 and the alignment marker 116a.

After formation of the oxide layer 164, the oxide layer 164 and bulk regions 160 of the integrated circuit dies 124 and 128 are planarized and the lid bonding layer 182 is formed on the resulting planarized surface 127. A lid 180 is then formed on the lid bonding layer 182. The lid 180 thus covers the integrated circuit dies 124 and 128 and the oxide layer 164. The lid 180 provides mechanical support for the microelectronic structure 100 comprising the integrated circuit dies 124 and 128 once the carrier wafer 104 is removed.

In any of the embodiments described or referenced herein, the liner layer 168 can comprise silicon and oxygen (e.g., SiOₓ, SiO₂), silicon and nitrogen (e.g., Si₃N₄, SiₓN_{y}), silicon, carbon, and nitrogen (e.g., SiCN), or another suitable material. In any of the embodiments described or referenced herein, the bonding layer 182 can comprise any of the materials described herein that can be part of the bonding layer 108. In any of the embodiments described or referenced herein, the lid 180 can comprise any of the materials described herein that can be part of carrier wafer 104. In any of the embodiments described or referenced herein, the oxide layer 164 can comprise oxygen, silicon, and oxygen (e.g., SiOₓ, SiO₂), or any other suitable material comprising oxygen.

FIG. 1F is a cross-sectional view of the microelectronic structure 100 after removal of the carrier wafer 104. Removal of the carrier wafer 104 comprises the removal of the bonding layer 108 from the die bonding layers 158 and the alignment marker portions 118. The resulting microelectronic structure 100 comprising integrated circuit die 124 and 128, oxide layer 164, and lid 180 can be referred to as a reconstituted wafer and the integrated circuit dies 124 and 128 can be referred to as reconstituted die.

FIG. 1G is a cross-sectional view of the reconstituted wafer 100 after formation of a wafer bonding layer 184 on the reconstituted wafer 100. The wafer bonding layer 184 enables the bonding of the reconstituted wafer to another structure, such as another wafer. Formation of the wafer bonding layer 184 can utilize the alignment markers 116 to align the wafer bonding layer 184 to the reconstituted wafer 100. For example, the alignment markers 116 can be used for alignment registration. That is, the alignment markers 116 can be aligned with corresponding alignment features on a photolithography mask used in the formation of the wafer bonding layer 184.

Vias 186 that extend from conductive contacts 140 of the integrated circuit die 124 and 128 to a surface 190 of the wafer bonding layer 184 that is distal from the integrated circuit die 124 and 128 are formed after formation of the wafer bonding layer 184. Thus, each of the vias 186 extends through one of the die bonding layers 158 and the wafer bonding layer 184.

The wafer bonding layer 184 comprises a dummification structure 188 positioned laterally outside of the outer lateral boundaries of the reconstituted dies 124 and 128. In some embodiments, dummification structures can comprise copper, aluminum, titanium, or another suitable metal. Dummification structures positioned laterally outside of the outer lateral boundaries of the reconstituted die can provide for a more uniform metal density in the wafer bonding layer 184, which can aid a planarization method (e.g., CMP) in achieving a more planar surface 190 of the wafer bonding layer 184.

In any of the embodiments described or referenced herein, the wafer bonding layer 184 can comprise any of the materials mentioned that can be part of the bonding layer 108 or any other suitable material. In any of the embodiments described or referenced herein, the vias 186 can comprise copper, aluminum, titanium, or other suitable conductive material.

FIG. 1H is a cross-sectional view of the reconstituted wafer 100 after attachment of an interposer 192 to the reconstituted wafer 100. The interposer 192 comprises a metallization region 193 and a substrate region 194, with the metallization region 193 positioned between the reconstituted wafer 100 and the substrate region 194. The metallization region 193 comprises conductive contacts 195 at surface 196 of the interposer 192, metal layers 197 with metal lines 198, and vias 199. Each of the vias 199 connects metal lines 198 of different metal layers 197 or a metal line 198 to a conductive contact 195. In some embodiments, the metal layers 197 can be separated by an inter-layer dielectric (ILD). The ILDs 101 can comprise a suitable nitride or oxide, such as silicon nitride (Si₃N₄), silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen).

The interposer 192 provides a conductive connection between conductive contacts 140 of the integrated circuit dies 124 and 128 (e.g., metal lines 103 and 105), and conductive connections between conductive contacts 140 of the integrated circuit dies 124 and 128 and vias 107. The metal layers 197 can be referred to as redistribution layers (RDLs). The substrate region 194 can be a substrate upon which the metallization region 193 is formed. The substrate region 194 can comprise silicon, sapphire, glass, or other suitable material. In embodiments where the substrate region 194 comprises silicon, the vias 107 can be thru-silicon vias (TSVs).

The interposer 192 can be attached to the wafer bonding layer 184 via hybrid bonding, that is, by bonding of dielectric regions on a surface of the wafer bonding layer 184 to dielectric portions (e.g., the top-most ILD 101 layer) of the surface 196 of the interposer 192 and bonding of the vias 186 extending through the die bonding layers 158 and the wafer bonding layer 184 to the conductive contacts 195 of the interposer 192. In some embodiments, the wafer bonding layer 184 is transparent, and attachment of the interposer 192 to the wafer bonding layer 184 can utilize the alignment markers 116 to align the interposer 192 to the wafer bonding layer 184.

FIG. 1I is a cross-sectional view of the microelectronic structure 100 after thinning of the substrate region 194 to expose the vias 107 and formation of conductive contacts 109 on the exposed vias. The conductive contacts 109 can be solder balls, pads, bumps, microbumps, pillars, micropillars, or other suitable structures. The conductive contacts 109 can comprise copper, silver, lead, tin, nickel, titanium, or other suitable material.

FIG. 1J is a cross-sectional view of an example integrated circuit component 111 comprising the microelectronic structure of FIG. 1I. The integrated circuit component 111 comprises the microelectronic structure 100 of FIG. 1I attached to a package substrate 113 by conductive contacts 115. The integrated circuit component 111 comprises an underfill layer 117 that substantially fills in the volumes between the package substrate 113 and the interposer 192. In some embodiments, the underfill layer 117 can comprise an epoxy, encapsulant, or adhesive. The package substrate 113 can comprise silicon, ceramic, amorphous solid glass (such as aluminosilicate, borosilicate, alumino-borosilicate, silica, and fused silica), FR-4 printed circuit board (PCB) material, ABF (Ajinomoto Build-up Film) or other suitable material. The package substrate 113 can further comprise one or more metal layers and vias (not shown) that provide a conductive connection between the conductive contacts 115 and the coupling components 119 of the package. The coupling components 119 can comprise solder balls, pads, bumps, or other suitable structures.

While FIGS. 1H-1J illustrate an embodiment of a reconstituted wafer attached to an interposer via hybrid bonding, in other embodiments, a reconstituted wafer can be attached to other components, such as another reconstituted wafer or package substrate, with or without any intervening structure, such as a wafer bonding layer, between the reconstituted wafer and the other component.

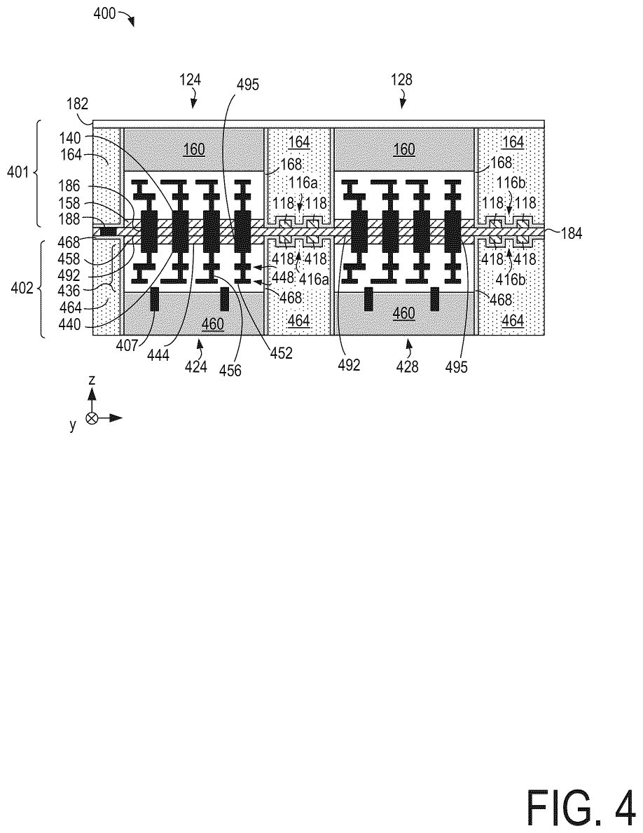

FIG. 4 is a cross-sectional view of an example microelectronic structure 400 comprising a first reconstituted wafer attached to a second reconstituted wafer. The microelectronic structure 400 comprises the reconstituted wafer of FIG. 1F (relabeled as 401 in FIG. 4) attached to a second reconstituted wafer 402 via the wafer bonding layer 184. The reconstituted wafer 402 is similar in structure to the reconstituted wafer 401. For example, the reconstituted wafer 402 comprises a pair of integrated circuit die 424 and 428, a liner layer 468, alignment markers 416 (416a, 416b) comprising alignment marker portions 418, and an oxide layer 464. The reconstituted wafers 401 and 402 are attached by hybrid bonding of each of the wafers 401 to 402 the wafer bonding layer 184. The integrated circuit dies 424 and 428 each comprise a metallization stack 436 comprising a plurality of metal layers 448 comprising metal lines 452 and vias 456, and conductive contacts 440 at a surface 444 of the integrated circuit dies 424 and 428. The second reconstituted wafer 402 comprises die bonding layers 458 and conductive contacts 495 at a surface 492 of the second reconstituted wafer 402. The integrated circuit dies 424 and 428 further comprise vias 407 that extend through a substrate region 460 of the integrated circuit dies 424 and 428. In embodiments where the substrate regions 460 comprise silicon, the vias 407 can be through-silicon vias (TSVs). Features or structures in the second reconstituted wafer 402 having similar numbers as in the reconstituted wafer 401 (468 and 168, 464 and 164, etc.) can comprise any of the materials described above as being used in the corresponding feature or structure in the reconstituted wafer 401.

Prior to attachment of the second reconstituted wafer 402 to the reconstituted wafer 401 to form the microelectronic structure 400, the conductive contacts 495 are formed in the die bonding layers 458. The attachment of the second reconstituted wafer 402 to reconstituted wafer 401 can comprise hybrid bonding the reconstituted wafer 401 to the wafer bonding layer 184 and the reconstituted wafer 402 to the wafer bonding layer 184. For example, to create the hybrid bond between the reconstituted wafer 402 and the wafer bonding layer 184, the dielectric regions of the surface 492 of the second reconstituted wafer 402 are bonded to the dielectric regions on a surface of the wafer bonding layer 184 and the conductive contacts 495 at the surface 492 of the second reconstituted wafer 402 are bonded to vias 186 extending through the wafer bonding layer 184. Attachment of the second reconstituted wafer 402 to the reconstituted wafer 401 can comprise utilizing the alignment markers 116 embedded in the reconstituted wafer 401 to enable alignment of the reconstituted wafer 402 to the reconstituted wafer 401.

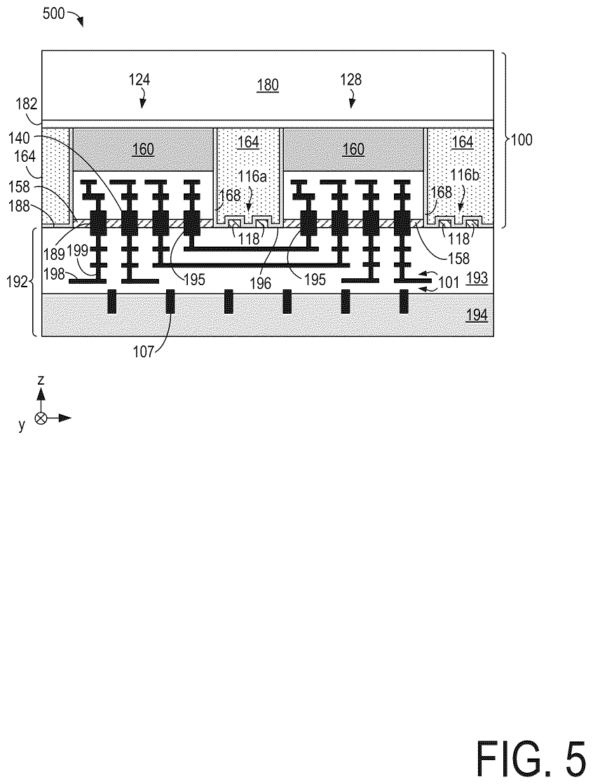

FIG. 5 is a cross-sectional view of a microelectronic structure 500 comprising a reconstituted wafer attached to an interposer without an intervening wafer bonding layer. The microelectronic structure 500 comprises the reconstituted wafer 100 of FIG. 1F attached to the interposer 192 without the wafer bonding layer 184 positioned between the reconstituted wafer and the interposer 192. Prior to attachment of the interposer 192 to the reconstituted wafer 100 to form the microelectronic structure 500, vias 189 are formed in the die bonding layers 158. Each of the vias 189 is attached to one of the conductive contacts 140 and one of the conductive contacts 195 and extends a die bonding layer 158. The attachment of the interposer 192 to reconstituted wafer can comprise hybrid bonding of the two components together. That is, the dielectric regions of the surface 196 of the interposer 192 (e.g., a top ILD layer 101) are bonded to the dielectric regions of the die bonding layers 158 and the conductive contacts 195 at the surface of the interposer 192 are bonded to the vias 189. Attachment of the interposer 192 to the reconstituted wafer 100 can comprise utilizing the alignment markers 116 embedded in the reconstituted wafer 100 to enable alignment of the interposer 192 to the reconstituted wafer 100. By not utilizing the wafer bonding layer 184 to bond the reconstituted wafer 100 to the interposer 192, a thinner overall microelectronic structure 500 can be realized.

The microelectronic structures 400 and 500, with a reconstituted wafer attached to a second reconstituted wafer or an interposer without a wafer bonding layer, can be packaged as illustrated in FIG. 1J or in any other manner to create an integrated circuit component comprising reconstituted die with embedded alignment markers.

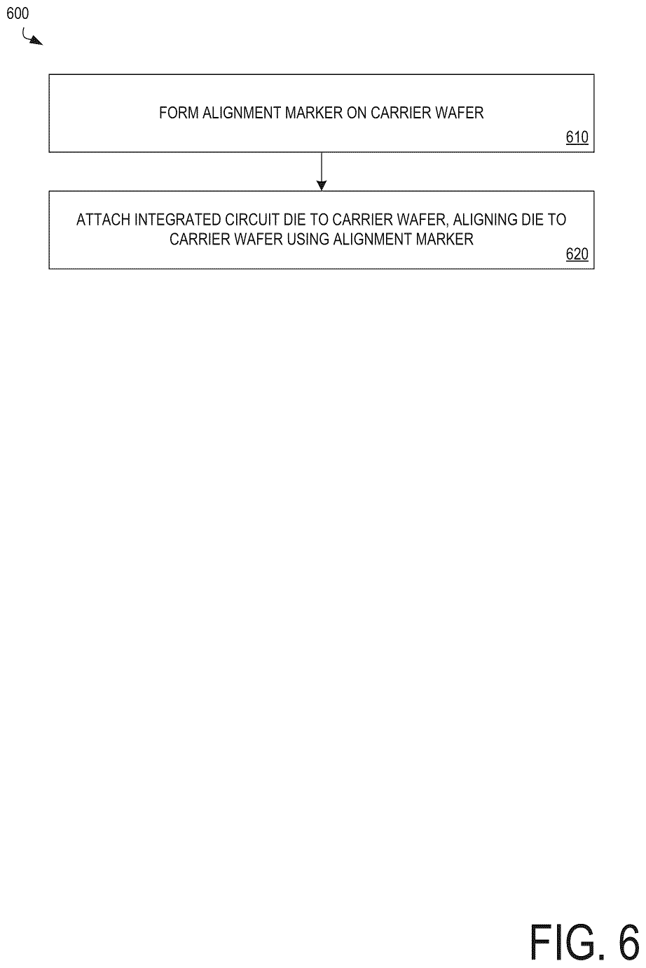

FIG. 6 is an example method of fabricating a microelectronic structure comprising embedded alignment markers. The method 600 can be performed by, for example, an integrated circuit component manufacturer. At 610, forming an alignment marker is formed on a carrier wafer. At 620, an integrated circuit die is attached to a surface of the carrier wafer, the integrated circuit die having a die outer lateral boundary, the attaching the integrated circuit die to the surface of the carrier wafer comprising aligning the integrated circuit die to the carrier wafer in part using the alignment marker, wherein the alignment marker is located outside of the die outer lateral boundary after attachment of the integrated circuit die to the carrier wafer.

In other embodiments, the method 600 may have additional elements. For example, the integrated circuit die can be a first integrated circuit die, and the method 600 can further comprise attaching a second integrated circuit die to the carrier wafer. In another example, the method 600 can further comprise separating the carrier wafer from the first integrated circuit die, the second integrated circuit die, and the alignment marker.

The integrated circuit components and microelectronic structures or assemblies described herein can be used in any processor unit or integrated circuit component described or referenced herein. An integrated circuit component comprising embedded alignment markers can be attached to a printed circuit board (motherboard, mainboard). In some embodiments, one or more additional integrated circuit components or other components (e.g., battery, memory, antenna) can be attached to the printed circuit board. In some embodiments, the printed circuit board and the integrated circuit component can be located in a computing device that comprises a housing that encloses the printed circuit board and the integrated circuit component.

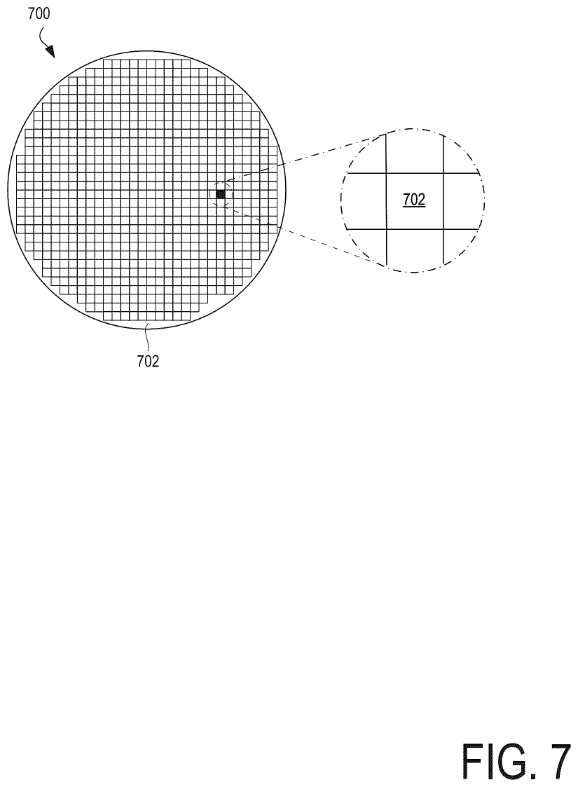

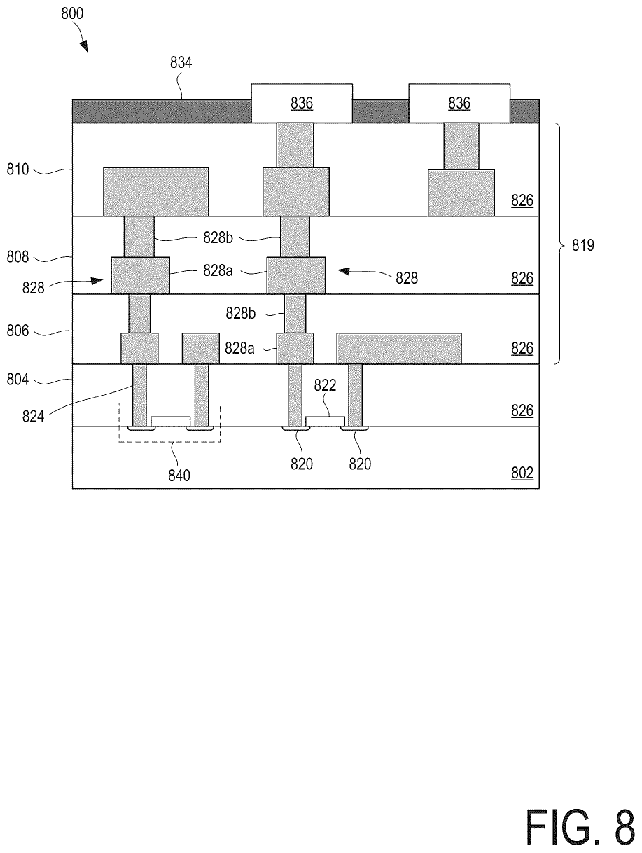

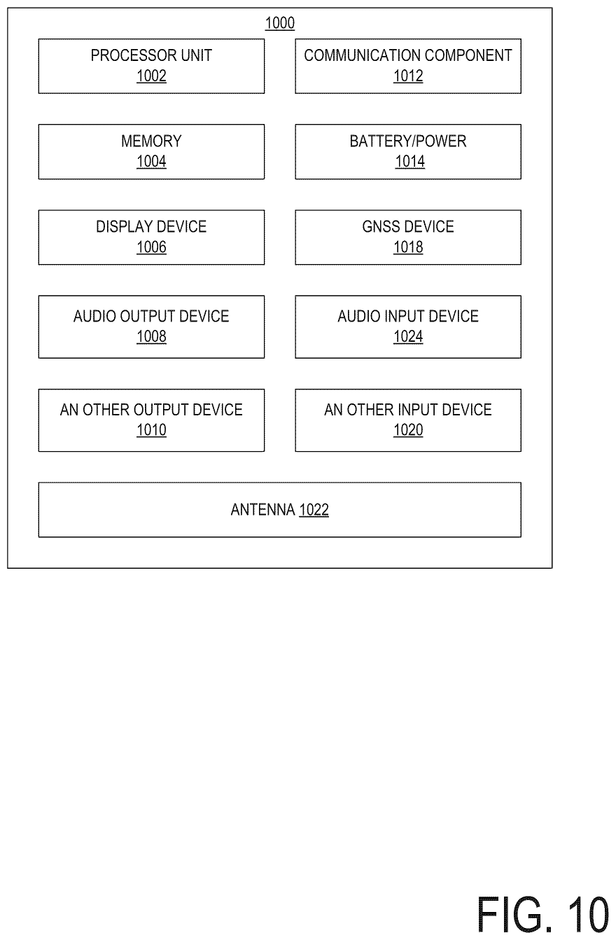

FIG. 7 is a top view of a wafer 700 and dies 702 that may be included in any of the microelectronic assemblies or structures disclosed herein. The wafer 700 may be composed of semiconductor material and may include one or more dies 702 having integrated circuit structures formed on a surface of the wafer 700. The individual dies 702 may be a repeating unit of an integrated circuit product that includes any suitable integrated circuit. After the fabrication of the semiconductor product is complete, the wafer 700 may undergo a singulation process in which the dies 702 are separated from one another to provide discrete “chips” of the integrated circuit product. The die 702 may be any of the reconstituted disclosed herein (e.g., 124, 128). The die 702 may include one or more transistors (e.g., some of the transistors 840 of FIG. 8, discussed below), supporting circuitry to route electrical signals to the transistors, passive components (e.g., signal traces, resistors, capacitors, or inductors), and/or any other integrated circuit components. In some embodiments, the wafer 700 or the die 702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 702. For example, a memory array formed by multiple memory devices may be formed on a same die 702 as a processor unit (e.g., the processor unit 1002 of FIG. 10) or other logic that is configured to store information in the memory devices or execute instructions stored in the memory array. Various ones of the microelectronic assemblies or structures disclosed herein may be manufactured using a die-to-wafer assembly technique in which some die are attached to a wafer 700 that include others of the die, and the wafer 700 is subsequently singulated.

FIG. 8 is a cross-sectional side view of an integrated circuit device 800 that may be included in any of the microelectronic assemblies or structures disclosed herein. One or more of the integrated circuit devices 800 may be included in one or more dies 702 (FIG. 7). The integrated circuit device 800 may be formed on a die substrate 802 (e.g., the wafer 700 of FIG. 7) and may be included in a die (e.g., the die 702 of FIG. 7). The die substrate 802 may be a semiconductor substrate composed of semiconductor material systems including, for example, n-type or p-type materials systems (or a combination of both). The die substrate 802 may include, for example, a crystalline substrate formed using a bulk silicon or a silicon-on-insulator (SOI) substructure. In some embodiments, the die substrate 802 may be formed using alternative materials, which may or may not be combined with silicon, that include, but are not limited to, germanium, carbon, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an integrated circuit device 800 may be used. The die substrate 802 may be part of a singulated die (e.g., the dies 702 of FIG. 7) or a wafer (e.g., the wafer 700 of FIG. 7).

The integrated circuit device 800 may include one or more device layers 804 disposed on the die substrate 802. The device layer 804 may include features of one or more transistors 840 (e.g., metal oxide semiconductor field-effect transistors (MOSFETs)) formed on the die substrate 802. The transistors 840 may include, for example, one or more source and/or drain (S/D) regions 820, a gate 822 to control current flow between the S/D regions 820, and one or more S/D contacts 824 to route electrical signals to/from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, nanowire transistors, forksheet, or complementary FET (CFET) transistors.

A transistor 840 may include a gate 822 formed of at least two layers, a gate dielectric, and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 840 along the source-channel-drain direction, the gate electrode may consist of a U-shaped structure that includes a bottom portion substantially parallel to the surface of the die substrate 802 and two sidewall portions that are substantially perpendicular to the top surface of the die substrate 802. In other embodiments, at least one of the metal layers that form the gate electrode may simply be a planar layer that is substantially parallel to the top surface of the die substrate 802 and does not include sidewall portions substantially perpendicular to the top surface of the die substrate 802. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of individual transistors 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 820 may be formed using one or more alternate semiconductor materials such as germanium or a group III-V material or alloy. In further embodiments, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the integrated circuit device 800.

The interconnect structures 828 may be arranged within the interconnect layers 806-810 to route electrical signals according to a wide variety of designs; in particular, the arrangement is not limited to the particular configuration of interconnect structures 828 depicted in FIG. 8. Although a particular number of interconnect layers 806-810 is depicted in FIG. 8, embodiments of the present disclosure include integrated circuit devices having more or fewer interconnect layers than depicted.

In some embodiments, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page and/or in a direction across the page from the perspective of FIG. 8. The vias 828b may be arranged to route electrical signals in a direction of a plane that is substantially perpendicular to the surface of the die substrate 802 upon which the device layer 804 is formed. In some embodiments, the vias 828b may electrically couple lines 828a of different interconnect layers 806-810 together.

The interconnect layers 806-810 may include a dielectric material 826 disposed between the interconnect structures 828, as shown in FIG. 8. In some embodiments, dielectric material 826 disposed between the interconnect structures 828 in different ones of the interconnect layers 806-810 may have different compositions; in other embodiments, the composition of the dielectric material 826 between different interconnect layers 806-810 may be the same. The device layer 804 may include a dielectric material 826 disposed between the transistors 840 and a bottom layer of the metallization stack as well. The dielectric material 826 included in the device layer 804 may have a different composition than the dielectric material 826 included in the interconnect layers 806-810; in other embodiments, the composition of the dielectric material 826 in the device layer 804 may be the same as a dielectric material 826 included in any one of the interconnect layers 806-810.

A first interconnect layer 806 (referred to as Metal 1 or “M1”) may be formed directly on the device layer 804. In some embodiments, the first interconnect layer 806 may include lines 828a and/or vias 828b, as shown. The lines 828a of the first interconnect layer 806 may be coupled with contacts (e.g., the S/D contacts 824) of the device layer 804. The vias 828b of the first interconnect layer 806 may be coupled with the lines 828a of a second interconnect layer 808.

The second interconnect layer 808 (referred to as Metal 2 or “M2”) may be formed directly on the first interconnect layer 806. In some embodiments, the second interconnect layer 808 may include via 828b to couple the lines 828 of the second interconnect layer 808 with the lines 828a of a third interconnect layer 810. Although the lines 828a and the vias 828b are structurally delineated with a line within individual interconnect layers for the sake of clarity, the lines 828a and the vias 828b may be structurally and/or materially contiguous (e.g., simultaneously filled during a dual-damascene process) in some embodiments.

The third interconnect layer 810 (referred to as Metal 3 or “M3”) (and additional interconnect layers, as desired) may be formed in succession on the second interconnect layer 808 according to similar techniques and configurations described in connection with the second interconnect layer 808 or the first interconnect layer 806. In some embodiments, the interconnect layers that are “higher up” in the metallization stack 819 in the integrated circuit device 800 (i.e., farther away from the device layer 804) may be thicker than the interconnect layers that are lower in the metallization stack 819, with lines 828a and vias 828b in the higher interconnect layers being thicker than those in the lower interconnect layers.

The integrated circuit device 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to external devices. For example, solder bonds may be formed on the one or more conductive contacts 836 to mechanically and/or electrically couple an integrated circuit die including the integrated circuit device 800 with another component (e.g., a printed circuit board). The integrated circuit device 800 may include additional or alternate structures to route the electrical signals from the interconnect layers 806-810; for example, the conductive contacts 836 may include other analogous features (e.g., posts) that route the electrical signals to external components. The conductive contacts 836 may serve as the conductive contacts 140 or 195, as appropriate.

In some embodiments in which the integrated circuit device 800 is a double-sided die, the integrated circuit device 800 may include another metallization stack (not shown) on the opposite side of the device layer(s) 804. This metallization stack may include multiple interconnect layers as discussed above with reference to the interconnect layers 806-810, to provide conductive pathways (e.g., including conductive lines and vias) between the device layer(s) 804 and additional conductive contacts (not shown) on the opposite side of the integrated circuit device 800 from the conductive contacts 836.

In other embodiments in which the integrated circuit device 800 is a double-sided die, the integrated circuit device 800 may include one or more through silicon vias (TSVs) through the die substrate 802; these TSVs may make contact with the device layer(s) 804, and may provide conductive pathways between the device layer(s) 804 and additional conductive contacts (not shown) on the opposite side of the integrated circuit device 800 from the conductive contacts 836. In some embodiments, TSVs extending through the substrate can be used for routing power and ground signals from conductive contacts on the opposite side of the integrated circuit device 800 from the conductive contacts 836 to the transistors 840 and any other components integrated into the die 800, and the metallization stack 819 can be used to route I/O signals from the conductive contacts 836 to transistors 840 and any other components integrated into the die 800.

Multiple integrated circuit devices 800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

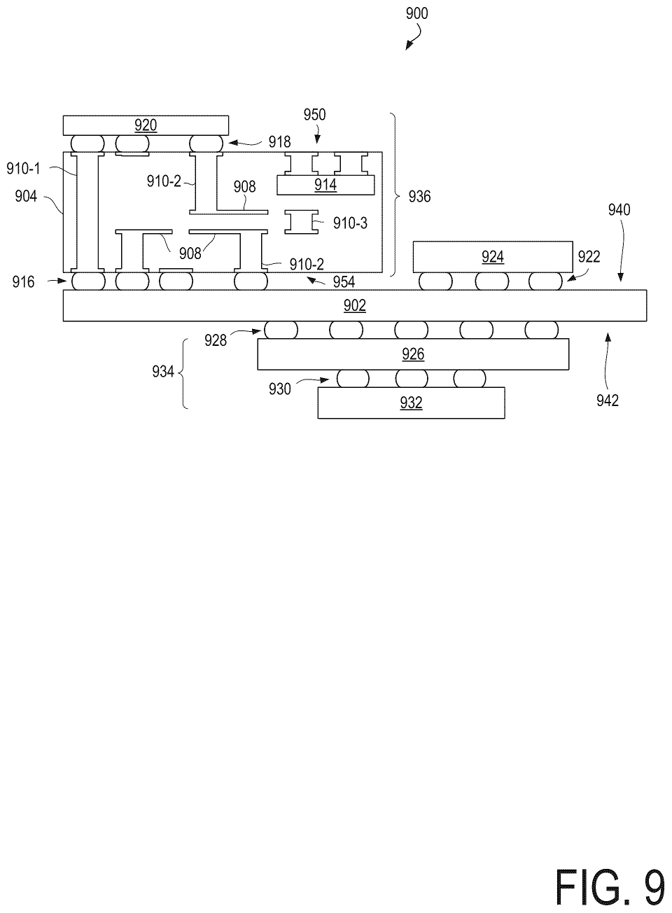

FIG. 9 is a cross-sectional side view of an integrated circuit device assembly 900 that may include any of the microelectronic assemblies or structures disclosed herein. The integrated circuit device assembly 900 includes a number of components disposed on a circuit board 902 (which may be a motherboard, system board, mainboard, etc.). The integrated circuit device assembly 900 includes components disposed on a first face 940 of the circuit board 902 and an opposing second face 942 of the circuit board 902; generally, components may be disposed on one or both faces 940 and 942. Any of the integrated circuit components discussed below with reference to the integrated circuit device assembly 900 may take the form of any suitable ones of the embodiments of the microelectronic assemblies or structures disclosed herein.

In some embodiments, the circuit board 902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 902. In other embodiments, the circuit board 902 may be a non-PCB substrate. The integrated circuit device assembly 900 illustrated in FIG. 9 includes a package-on-interposer structure 936 coupled to the first face 940 of the circuit board 902 by coupling components 916. The coupling components 916 may electrically and mechanically couple the package-on-interposer structure 936 to the circuit board 902, and may include solder balls (as shown in FIG. 9), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 916 may serve as the coupling components illustrated or described for any of the substrate assembly or substrate assembly components described herein, as appropriate.

The package-on-interposer structure 936 may include an integrated circuit component 920 coupled to an interposer 904 by coupling components 918. The coupling components 918 may take any suitable form for the application, such as the forms discussed above with reference to the coupling components 916. Although a single integrated circuit component 920 is shown in FIG. 9, multiple integrated circuit components may be coupled to the interposer 904; indeed, additional interposers may be coupled to the interposer 904. The interposer 904 may provide an intervening substrate used to bridge the circuit board 902 and the integrated circuit component 920.

The integrated circuit component 920 may be a packaged or unpackaged integrated circuit product that includes one or more integrated circuit dies (e.g., the die 702 of FIG. 7, the integrated circuit device 800 of FIG. 8) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 920, a single monolithic integrated circuit die comprises solder bumps attached to contacts on the die. The solder bumps allow the die to be directly attached to the interposer 904. The integrated circuit component 920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 920 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 904 may spread connections to a wider pitch or reroute a connection to a different connection. For example, the interposer 904 may couple the integrated circuit component 920 to a set of ball grid array (BGA) conductive contacts of the coupling components 916 for coupling to the circuit board 902. In the embodiment illustrated in FIG. 9, the integrated circuit component 920 and the circuit board 902 are attached to opposing sides of the interposer 904; in other embodiments, the integrated circuit component 920 and the circuit board 902 may be attached to a same side of the interposer 904. In some embodiments, three or more components may be interconnected by way of the interposer 904.

In some embodiments, the interposer 904 may be formed as a PCB, including multiple metal layers separated from one another by layers of dielectric material and interconnected by electrically conductive vias. In some embodiments, the interposer 904 may be formed of an epoxy resin, a fiberglass-reinforced epoxy resin, an epoxy resin with inorganic fillers, a ceramic material, or a polymer material such as polyimide. In some embodiments, the interposer 904 may be formed of alternate rigid or flexible materials that may include the same materials described above for use in a semiconductor substrate, such as silicon, germanium, and other group III-V and group IV materials. The interposer 904 may include metal interconnects 908 and vias 910, including but not limited to through hole vias 910-1 (that extend from a first face 950 of the interposer 904 to a second face 954 of the interposer 904), blind vias 910-2 (that extend from the first or second faces 950 or 954 of the interposer 904 to an internal metal layer), and buried vias 910-3 (that connect internal metal layers).

In some embodiments, the interposer 904 can comprise a silicon interposer. Through silicon vias (TSV) extending through the silicon interposer can connect connections on a first face of a silicon interposer to an opposing second face of the silicon interposer. In some embodiments, an interposer 904 comprising a silicon interposer can further comprise one or more routing layers to route connections on a first face of the interposer 904 to an opposing second face of the interposer 904.

The interposer 904 may further include embedded devices 914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art.

The integrated circuit device assembly 900 may include an integrated circuit component 924 coupled to the first face 940 of the circuit board 902 by coupling components 922. The coupling components 922 may take the form of any of the embodiments discussed above with reference to the coupling components 916, and the integrated circuit component 924 may take the form of any of the embodiments discussed above with reference to the integrated circuit component 920.

The integrated circuit device assembly 900 illustrated in FIG. 9 includes a package-on-package structure 934 coupled to the second face 942 of the circuit board 902 by coupling components 928. The package-on-package structure 934 may include an integrated circuit component 926 and an integrated circuit component 932 coupled together by coupling components 930 such that the integrated circuit component 926 is disposed between the circuit board 902 and the integrated circuit component 932. The coupling components 928 and 930 may take the form of any of the embodiments of the coupling components 916 discussed above, and the integrated circuit components 926 and 932 may take the form of any of the embodiments of the integrated circuit component 920 discussed above. The package-on-package structure 934 may be configured in accordance with any of the package-on-package structures known in the art.

FIG. 10 is a block diagram of an example electrical device 1000 that may include one or more of the microelectronic assemblies or structures disclosed herein. For example, any suitable ones of the components of the electrical device 1000 may include one or more of the integrated circuit device assemblies 900, integrated circuit components 920, integrated circuit devices 800, or integrated circuit dies 702 disclosed herein, and may be arranged in any of the microelectronic assemblies or structures disclosed herein. A number of components are illustrated in FIG. 10 as included in the electrical device 1000, but any one or more of these components may be omitted or duplicated, as suitable for the application. In some embodiments, some or all of the components included in the electrical device 1000 may be attached to one or more motherboards mainboards, or system boards. In some embodiments, one or more of these components are fabricated onto a single system-on-a-chip (SoC) die.

Additionally, in various embodiments, the electrical device 1000 may not include one or more of the components illustrated in FIG. 10, but the electrical device 1000 may include interface circuitry for coupling to the one or more components. For example, the electrical device 1000 may not include a display device 1006, but may include display device interface circuitry (e.g., a connector and driver circuitry) to which a display device 1006 may be coupled. In another set of examples, the electrical device 1000 may not include an audio input device 1024 or an audio output device 1008, but may include audio input or output device interface circuitry (e.g., connectors and supporting circuitry) to which an audio input device 1024 or audio output device 1008 may be coupled.

The electrical device 1000 may include one or more processor units 1002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1000 may include a memory 1004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1004 may include memory that is located on the same integrated circuit die as the processor unit 1002. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1000 can comprise one or more processor units 1002 that are heterogeneous or asymmetric to another processor unit 1002 in the electrical device 1000. There can be a variety of differences between the processing units 1002 in a system in terms of a spectrum of metrics of merit including architectural, microarchitectural, thermal, power consumption characteristics, and the like. These differences can effectively manifest themselves as asymmetry and heterogeneity among the processor units 1002 in the electrical device 1000.

In some embodiments, the electrical device 1000 may include a communication component 1012 (e.g., one or more communication components). For example, the communication component 1012 can manage wireless communications for the transfer of data to and from the electrical device 1000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1012 may operate in accordance with other wireless protocols in other embodiments. The electrical device 1000 may include an antenna 1022 to facilitate wireless communications and/or to receive other wireless communications (such as AM or FM radio transmissions).

In some embodiments, the communication component 1012 may manage wired communications, such as electrical, optical, or any other suitable communication protocols (e.g., IEEE 802.3 Ethernet standards). As noted above, the communication component 1012 may include multiple communication components. For instance, a first communication component 1012 may be dedicated to shorter-range wireless communications such as Wi-Fi or Bluetooth, and a second communication component 1012 may be dedicated to longer-range wireless communications such as global positioning system (GPS), EDGE, GPRS, CDMA, WiMAX, LTE, EV-DO, or others. In some embodiments, a first communication component 1012 may be dedicated to wireless communications, and a second communication component 1012 may be dedicated to wired communications.

The electrical device 1000 may include battery/power circuitry 1014. The battery/power circuitry 1014 may include one or more energy storage devices (e.g., batteries or capacitors) and/or circuitry for coupling components of the electrical device 1000 to an energy source separate from the electrical device 1000 (e.g., AC line power).

The electrical device 1000 may include a display device 1006 (or corresponding interface circuitry, as discussed above). The display device 1006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1000 may include an audio output device 1008 (or corresponding interface circuitry, as discussed above). The audio output device 1008 may include any embedded or wired or wirelessly connected external device that generates an audible indicator, such as speakers, headsets, or earbuds.

The electrical device 1000 may include an audio input device 1024 (or corresponding interface circuitry, as discussed above). The audio input device 1024 may include any embedded or wired or wirelessly connected device that generates a signal representative of a sound, such as microphones, microphone arrays, or digital instruments (e.g., instruments having a musical instrument digital interface (MIDI) output). The electrical device 1000 may include a Global Navigation Satellite System (GNSS) device 1018 (or corresponding interface circuitry, as discussed above), such as a Global Positioning System (GPS) device. The GNSS device 1018 may be in communication with a satellite-based system and may determine a geolocation of the electrical device 1000 based on information received from one or more GNSS satellites, as known in the art.

The electrical device 1000 may include another output device 1010 (or corresponding interface circuitry, as discussed above). Examples of the other output device 1010 may include an audio codec, a video codec, a printer, a wired or wireless transmitter for providing information to other devices, or an additional storage device.

The electrical device 1000 may include another input device 1020 (or corresponding interface circuitry, as discussed above). Examples of the other input device 1020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, any other sensor, or a radio frequency identification (RFID) reader.

The electrical device 1000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1000 may be any other electronic device that processes data. In some embodiments, the electrical device 1000 may comprise multiple discrete physical components. Given the range of devices that the electrical device 1000 can be manifested as in various embodiments, in some embodiments, the electrical device 1000 can be referred to as a computing device or a computing system.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C. Furthermore, as used in this application and the claims, a list of items joined by the term “one of” can mean any one of the listed items. For example, the phrase “one of A, B, and C” can mean A, B, or C.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an apparatus comprising: a plurality of integrated circuit dies arranged laterally, wherein individual of the plurality of integrated circuit dies have an outer lateral boundary and physically adjacent integrated circuit dies of the plurality of integrated circuit dies are spaced laterally; a plurality of first layers, individual of the plurality of first layers attached to a die surface of an integrated circuit die of the plurality of integrated circuit dies; and a structure comprising one or more structure portions, individual of the one or more structure portions having a structure surface coplanar with a surface of one of the plurality of first layers, the structure positioned at least partially between physically adjacent integrated circuit dies of the plurality of integrated circuit dies.

Example 2 the apparatus of clause 1, wherein one of the plurality of first layers comprises: silicon and oxygen; silicon and nitrogen; or silicon, nitrogen, and carbon.

Example 3 the apparatus of clause 1 or 2, further comprising a second layer comprising oxygen and having a second layer outer lateral boundary, the plurality of integrated circuit dies located within the second layer outer lateral boundary, the second layer substantially filling a volume between physically adjacent integrated circuit dies of the plurality of integrated circuit dies, the structure located within the second layer outer lateral boundary.

Example 4 the apparatus of clause 3, wherein one of the integrated circuit die comprises a sidewall, the apparatus further comprising a liner layer, the liner layer comprising a first liner layer portion positioned between the sidewall and the second layer and a second liner layer portion positioned between the structure and the second layer.

Example 5 the apparatus of clause 4, wherein the liner layer comprises: silicon and nitrogen; or silicon, nitrogen, and carbon.

Example 6 the apparatus of clause 3, wherein the die surface of one of the plurality of integrated circuit dies attached to one of the plurality of first layers is a first die surface, the one of the plurality of integrated circuit dies further comprising a second die surface opposite the first die surface, and the second die surface is coplanar with a surface of the second layer.

Example 7 the apparatus of any one of clauses 3-5, further comprising: a third layer comprising silicon that covers the plurality of integrated circuit dies; and a fourth layer positioned between the third layer and the plurality of integrated circuit dies, the fourth layer comprising: silicon and oxygen; silicon and nitrogen; or silicon, nitrogen, and carbon.

Example 8 the apparatus of any one of clauses 1-6, wherein the one or more structure portions comprise a metal.

Example 9 the apparatus of any one of clauses 1-6, wherein the one or more structure portions comprise copper, titanium, or tantalum.

Example 10 the apparatus of any one of clauses 1-6, wherein the one or more structure portions comprise a dielectric.

Example 11 the apparatus of any one of clauses 1-6, wherein the one or more structure portions comprise: silicon and oxygen; silicon and nitrogen; or aluminum and oxygen.

Example 12 the apparatus of any one of clauses 1-11, wherein the plurality of integrated circuit dies comprise a plurality of metal lines, the structure not connected to any of the plurality of metal lines.

Example 13 the apparatus of any one of clauses 1-6, wherein the one or more structure portions comprise one or more channels in a layer comprising a metal.

Example 14 the apparatus of any one of clauses 1-6, wherein the one or more structure portions comprise one or more channels in a layer comprising copper, titanium, or tantalum.

Example 15 the apparatus of any one of clauses 1-6, wherein the one or more structure portions comprise one or more channels in a layer comprising a dielectric.

Example 16 the apparatus of any one of clauses 1-6, wherein the one or more structure portions comprise one or more channels in a layer comprising: silicon and oxygen; silicon and nitrogen; or aluminum and oxygen.

Example 17 the apparatus of any one of clauses 1-16, wherein the one or more structure portions comprise have a thickness within a range of 50 nanometers to five microns.

Example 18 the apparatus of any one of clauses 1-17, wherein the one or more structure portions occupies a lateral area of about 10,000 square microns of less.

Example 19 the apparatus of any one of clauses 1-18, wherein the one or more structure portions comprise two orthogonally intersecting traces.

Example 20 the apparatus of any one of clauses 1-2 or 8-19, further comprising: a first die conductive contact located on the die surface of a first integrated circuit die of the plurality of integrated circuit dies; a second die conductive contact located on the die surface of a second integrated circuit die of the plurality of integrated circuit dies; a second layer attached to the structure and the plurality of first layers; a first via attached to the first die conductive contact and extending through the second layer and the first layer of the plurality of first layers attached to the die surface of the first integrated circuit die; and a second via attached to the second die conductive contact and extending through the second layer and the first layer of the plurality of first layers attached to the die surface of the second integrated circuit die.

Example 21 the apparatus of clause 20 further comprising an interposer, the interposer comprising: an interposer surface attached to the second layer; a first interposer conductive contact located on the interposer surface, the first interposer conductive contact attached to the first via; and a second interposer conductive contact located on the interposer surface, the second interposer conductive contact attached to the second via.

Example 22 the apparatus of clause 21, the interposer further comprising: a metal layer located within the interposer, the metal layer comprising a plurality of metal lines; a third via attached to the first interposer conductive contact and a first metal line of the plurality of metal lines; and a fourth via attached to the second interposer conductive contact and a second metal line of the plurality of metal lines.

Example 23 the apparatus of clause 20, wherein the plurality of integrated circuit dies is a first plurality of integrated circuit dies and the structure is a first structure having first structure portions, the apparatus further comprising a second structure comprising: a surface attached to the second layer; a second plurality of integrated circuit dies arranged laterally, wherein physically adjacent integrated circuit dies of the second plurality of integrated circuit dies are spaced laterally; a plurality of third layers, individual of the plurality of third layers attached to a surface of one of the second plurality of integrated circuit dies, wherein the third layer attached to the surface of a first integrated circuit die of the second plurality of integrated circuit dies comprises a third die conductive contact and the third layer attached to the surface of a second integrated circuit die of the second plurality of integrated circuit dies comprises a fourth die conductive contact, the third die conductive contact attached to the first via, the fourth die conductive contact attached to the second via; and a third structure having one or more third structure portions, individual of the one or more third structure portions coplanar with a surface of one of the plurality of third layers, the third structure positioned at least partially between physically adjacent integrated circuit dies of the second plurality of integrated circuit dies.

Example 24 the apparatus of any one of clauses 1-2 or 8-19, wherein the first layer of the plurality of first layers attached to the die surface of a first integrated circuit die of the plurality of integrated circuit dies comprises a first die conductive contact and the first layer of the plurality of first layers attached to the die surface of a second integrated circuit die of the plurality of integrated circuit dies comprises a second die conductive contact, the apparatus further comprising an interposer, the interposer comprising: an interposer surface attached to the plurality of first layers; a first interposer conductive contact located on the interposer surface, the first interposer conductive contact attached to the first die conductive contact; and a second interposer conductive contact located on the interposer surface, the second interposer conductive contact attached to the second die conductive contact.

Example 25 the apparatus of clause 24, the interposer further comprising: a metal layer comprising a plurality of metal lines; a first via attached to the first interposer conductive contact and a first metal line of the plurality of metal lines; and a second via attached the second interposer conductive contact and a second metal line of the plurality of metal lines.

Example 26 the apparatus of any one of clauses 1-2 or 8-19, wherein the plurality of integrated circuit dies is a first plurality of integrated circuit dies, the structure is a first structure comprising first structure portions, the apparatus further comprising: a first die conductive contact located on the die surface of a first integrated circuit die of the first plurality of integrated circuit dies; a second die conductive contact located on the die surface of a second integrated circuit die of the first plurality of integrated circuit dies; and a second structure comprising: a surface attached to the plurality of first layers; a second plurality of integrated circuit dies arranged laterally, wherein physically adjacent integrated circuit dies of the second plurality of integrated circuit dies are spaced laterally; a plurality of second layers, individual of the plurality of second layers attached to a surface of one of the second plurality of integrated circuit dies, wherein the second layer attached to the surface of a first integrated circuit die of the second plurality of integrated circuit dies comprises a third die conductive contact and the first layer of the plurality of first layers attached to the surface of a second integrated circuit die of the second plurality of integrated circuit dies comprises a fourth die conductive contact, the first die conductive contact attached to the third die conductive contact, the third die conductive contact attached to the second die conductive contact; and a third structure having one or more third structure portions, individual of the one or more third structure portions substantially coplanar with a surface of one of the plurality of second layers, the third structure positioned at least partially between physically adjacent integrated circuit die of the second plurality of integrated circuit dies.

Example 27 is an apparatus comprising: a plurality of integrated circuit dies arranged laterally, wherein individual of the plurality of integrated circuit dies have an outer lateral boundary and physically adjacent integrated circuit dies of the plurality of integrated circuit dies are spaced laterally; a plurality of first layers, individual of the first layers attached to a die surface of an integrated circuit die of the plurality of integrated circuit dies; a second layer comprising oxygen and having a second layer outer lateral boundary, the plurality of integrated circuit dies located within the second layer outer lateral boundary, the second layer substantially filling a volume between physically adjacent integrated circuit dies; and an alignment marker having an alignment marker surface substantially coplanar with a surface of one of the first layers, the alignment marker located within the second layer outer lateral boundary and outside the outer lateral boundary of individual integrated circuit die of the plurality of integrated circuit dies.

Example 28 the apparatus of clause 27, wherein one of the plurality of first layers comprises: silicon and oxygen; silicon and nitrogen; or silicon, nitrogen, and carbon.

Example 29 the apparatus of clause 27 or 28, wherein one of the integrated circuit die comprises a sidewall, the apparatus further comprising a liner layer, the liner layer comprising a first liner layer portion positioned between the sidewall and the second layer and a second liner layer portion positioned between the alignment marker and the second layer.

Example 30 the apparatus of clause 29, wherein the liner layer comprises: silicon and nitrogen; or silicon, nitrogen, and carbon.

Example 31 the apparatus of clause 27, wherein the die surface of one the plurality of integrated circuit dies attached to one of the plurality of first layers is a first die surface, the one of the plurality of integrated circuit dies further comprising a second die surface opposite the first die surface, the first die surface substantially coplanar with a surface of the second layer.

Example 32 the apparatus of any one of clauses 27-31, wherein the alignment marker is positioned between physically adjacent integrated circuit dies of the plurality of integrated circuit dies.

Example 33 the apparatus of clause 32, wherein a space between the physically adjacent integrated circuit dies is about 100 microns or less.

Example 34 the apparatus of any one of clauses 27-31, wherein the alignment marker is positioned between the outer lateral boundary of one of the plurality of integrated circuit dies and the second layer outer lateral boundary.

Example 35 the apparatus of any one of clauses 27-31, wherein the alignment marker comprises one or more traces comprising a metal.

Example 36 the apparatus of any one of clauses 27-31, wherein the alignment marker comprises one or more traces comprising copper, titanium, or tantalum.

Example 37 the apparatus of any one of clauses 27-31, wherein the alignment marker comprises one or more traces comprising a dielectric.

Example 38 the apparatus of any one of clauses 27-31, wherein the alignment marker comprises one or more traces comprising: silicon and oxygen; silicon and nitrogen; or aluminum and oxygen.

Example 39 the apparatus of any one of clauses 27-38, wherein the plurality of integrated circuit dies comprise a plurality of metal lines, the alignment marker not connected to any of the plurality of metal lines.

Example 40 the apparatus of any one of clauses 27-31, wherein the alignment marker comprises one or more channels in a layer comprising a metal.

Example 41 the apparatus of any one of clauses 27-31, wherein the alignment marker comprises one or more channels in a layer comprising copper, titanium, or tantalum.

Example 42 the apparatus of any one of clauses 27-31, wherein the alignment marker comprises one or more channels in a layer comprising a dielectric.

Example 43 the apparatus of any one of clauses 27-31, wherein the alignment marker comprises one or more channels in a layer comprising: silicon and oxygen; silicon and nitrogen; or aluminum and oxygen.

Example 44 the apparatus of any one of clauses 32-41, wherein the alignment marker one or more channels having a thickness within a range of 50 nanometers to five microns.

Example 45 the apparatus of any one of clauses 27-44, wherein the alignment marker occupies a lateral area of about 10,000 square microns of less.

Example 46 the apparatus of any one of clauses 27-44, wherein the alignment marker comprises two orthogonally intersecting traces.

Example 47 the apparatus of any one of clauses 27-46, further comprising: a third layer comprising silicon, the third layer covering the second layer and the plurality of integrated circuit dies; and a fourth layer positioned between the third layer and the plurality of integrated circuit dies, the fourth layer comprising: silicon and oxygen; silicon and nitrogen; or silicon, nitrogen, and carbon.

Example 48 the apparatus of any one of clauses 27-47, further comprising: a first die conductive contact located on the die surface of a first integrated circuit die; a second die conductive contact located on the die surface of a second integrated circuit die; a third layer attached to the alignment marker and the plurality of first layers; a first via attached to the first die conductive contact and extending through the second layer and the first layer of the plurality of first layers attached to the die surface of the first integrated circuit die; and a second via attached to the second die conductive contact and extending through the second layer and the first layer of the plurality of first layers attached to the die surface of the second integrated circuit die.

Example 49 the apparatus of clause 48, further comprising an interposer, the interposer comprising: an interposer surface attached to the third layer; a first interposer conductive contact located on the interposer surface, the first interposer conductive contact attached to the first via; and a second interposer conductive contact located on the interposer surface, the second interposer conductive contact attached to the second via.

Example 50 the apparatus of clause 49, the interposer further comprising: a metal layer located within the interposer, the metal layer comprising a plurality of metal lines; a third via attached to the first via and a first metal line of the plurality of metal lines; and a fourth via attached to the second via and a second metal line of the plurality of metal lines.

Example 51 the apparatus of clause 50, wherein the plurality of integrated circuit dies is a first plurality of integrated circuit die, the alignment marker is a first alignment marker, the alignment marker surface is a first alignment marker surface, the apparatus further comprising a structure, the structure comprising: a surface attached to the third layer; a second plurality of integrated circuit dies arranged laterally, wherein physically adjacent second integrated circuit dies of the second plurality of integrated circuit dies are spaced laterally; a plurality of fourth layers, individual of the plurality of fourth layers attached to a surface of one of the second plurality of integrated circuit dies, wherein the fourth layer attached to the surface of a first integrated circuit die of the second plurality of integrated circuit dies comprises a third die conductive contact and the fourth layer attached to the surface of a second integrated circuit die of the second plurality of integrated circuit dies comprises a fourth die conductive contact, the third die conductive contact attached to the first via, the fourth die conductive contact attached to second via; a fifth layer comprising oxygen and having a fifth layer outer lateral boundary, the fifth layer substantially filling a volume between physically adjacent integrated circuit dies of the second plurality of integrated circuit dies; and a second alignment marker having a second alignment marker surface substantially coplanar with a surface of one of the plurality of fourth layers, the second alignment marker located within the fifth layer outer lateral boundary and outside the outer lateral boundary of individual of the second plurality of integrated circuit dies.

Example 52 the apparatus of any one of clauses 27-40, wherein the first layer of the plurality of first layers attached to the die surface of a first integrated circuit die comprises a first die conductive contact and the first layer of the plurality of first layers attached to the die surface of a second integrated circuit die comprises a second die conductive contact, the apparatus further comprising an interposer, the interposer comprising: an interposer surface attached to the plurality of first layers; a first interposer conductive contact located on the interposer surface, the first interposer conductive contact attached to the first die conductive contact; and a second interposer conductive contact located on the interposer surface, the second interposer conductive contact attached to the second die conductive contact.

Example 53 the apparatus of clause 52, the interposer further comprising: a metal layer comprising a plurality of metal lines; a first via attached to the first interposer conductive contact and a first metal line of the plurality of metal lines; and a second via attached to the second interposer conductive contact and a second metal line of the plurality of metal lines.

Example 54 the apparatus of any one of clauses 27-47, wherein the plurality of integrated circuit dies is a first plurality of integrated circuit dies, the alignment marker is a first alignment marker, the apparatus further comprising: a first die conductive contact located on the die surface of a first integrated circuit die of the first plurality of integrated circuit dies; a second die conductive contact located on the die surface of a second integrated circuit die of the first plurality of integrated circuit dies; and a structure comprising: a surface attached to the plurality of first layers; a second plurality of integrated circuit dies arranged laterally, wherein physically adjacent integrated circuit dies of the second plurality of integrated circuit dies are spaced laterally; a plurality of third layers, individual of the plurality of third layers attached to a surface of one of the second plurality of integrated circuit dies, wherein the third layer attached to the surface of a first integrated circuit die of the second plurality of integrated circuit dies comprises a third die conductive contact and the first layer of the plurality of first layers attached to the surface of a second integrated circuit die of the second plurality of integrated circuit dies comprises a fourth die conductive contact, the first die conductive contact attached to the third die conductive contact, the second die conductive contact attached to the fourth die conductive contact; and a second alignment marker having a second alignment marker surface substantially coplanar with a surface of one of the plurality of third layers, the second alignment marker positioned at least partially between physically adjacent integrated circuit die of the second plurality of integrated circuit dies.

Example 55 the apparatus of clause 27, wherein the apparatus comprises an integrated circuit component comprising the plurality of integrated circuit dies.

Example 56 the apparatus of clause 55, wherein the integrated circuit component is attached to a printed circuit board.

Example 57 the apparatus of clause 56, wherein the integrated circuit component is a first integrated circuit component and one or more second integrated circuit components are attached to the printed circuit board.

Example 58 is a method comprising: forming an alignment marker on a carrier wafer; and attaching an integrated circuit die to a surface of the carrier wafer, the integrated circuit die having a die outer lateral boundary, attaching the integrated circuit die to the surface of the carrier wafer comprising aligning the integrated circuit die to the carrier wafer in part using the alignment marker, wherein the alignment marker is located outside of the die outer lateral boundary after attachment of the integrated circuit die to the carrier wafer.

Example 59 the method of clause 58, wherein the integrated circuit die is a first integrated circuit die, the method further comprising attaching a second integrated circuit die to the carrier wafer.

Example 60 the method of clause 59, further comprising forming a first layer comprising oxygen substantially filling a volume between the first integrated circuit die and the second integrated circuit die, the first layer covering the alignment marker.

Example 61 the method of clause 60, further comprising separating the carrier wafer from the first integrated circuit die, the second integrated circuit die, and the alignment marker.

Example 62 the method of clause 60 wherein the first layer comprises: silicon and oxygen; silicon and nitrogen; or silicon, nitrogen, and carbon.

Example 63 the method of clause 60, wherein the first integrated circuit die comprises a sidewall, the method further comprising forming a liner layer before forming the first layer, the liner layer comprising a first liner layer portion positioned between the sidewall and the first layer and a second liner layer portion positioned between the alignment marker and the first layer.

Example 64 the method of clause 63, wherein the liner layer comprises: silicon and nitrogen; or silicon, nitrogen, and carbon.

Example 65 the method of clause 60, wherein the first integrated circuit die comprises a first sidewall, the second integrated circuit die comprises a second sidewall, the alignment marker positioned between the first sidewall and the second sidewall.

Example 66 the method of any one of clauses 58-65, wherein the alignment marker comprises one or more traces comprising a metal.

Example 67 the method of any one of clauses 58-65, wherein the alignment marker comprises one or more traces comprising copper, titanium, or tantalum.

Example 68 the method of any one of clauses 58-65, wherein the alignment marker comprises one or more traces comprising a dielectric.

Example 69 the method of any one of clauses 58-65, wherein the alignment marker comprises one or more traces comprising: silicon and oxygen; silicon and nitrogen; or aluminum and oxygen.

Example 70 the method of any one of clauses 58-69, wherein the integrated circuit die comprises a plurality of metal lines, the alignment marker not connected to any of the plurality of metal lines.

Example 71 the method of any one of clauses 58-65, wherein the alignment marker comprises one or more channels in a layer comprising a metal.

Example 72 the method of any one of clauses 58-65, wherein the alignment marker comprises one or more channels in a layer comprising copper, titanium, or tantalum.

Example 73 the method of any one of clauses 58-65, wherein the alignment marker comprises one or more channels in a layer comprising a dielectric.

Example 74 the method of any one of clauses 58-65, wherein the alignment marker comprises one or more channels in a layer comprising: silicon and oxygen; silicon and nitrogen; or aluminum and oxygen.

Example 75 the method of any one of clauses 71-74, wherein the one or more channels have a thickness within a range of 50 nanometers to five microns.

Example 76 the method of any one of clauses 58-75, wherein the alignment marker occupies a lateral area of about 10,000 square microns of less.

Example 77 the method of any one of clauses 58-76, wherein the alignment marker comprises two orthogonally intersecting traces.

Example 78 the method of clause 59, wherein attaching the first integrated circuit die to the carrier wafer further comprises attaching the first integrated circuit die to the carrier wafer via a first die bonding layer, the first die bonding layer positioned between the carrier wafer and a die surface of the first integrated circuit die, wherein attaching the second integrated circuit die to carrier wafer further comprises attaching the second integrated circuit die to the carrier wafer via a second die bonding layer, the second die bonding layer positioned between the carrier wafer and a die surface of the second integrated circuit die, a surface of the alignment marker substantially coplanar with a surface of the first die bonding layer.

Example 79 the method of clause 78, wherein the first die bonding layer and the second die bonding layer comprise: silicon and oxygen; silicon and nitrogen; or silicon, nitrogen, and carbon.

Example 80 the method of clause 78, the method further comprising forming a first via in the first die bonding layer and a second via in the second die bonding layer, the first via attached to a first die conductive contact located on a surface of the first integrated circuit die, the second via attached to a second die conductive contact located on a surface of the second integrated circuit die.

Example 81 the method of clause 80, wherein the alignment marker comprises an alignment marker surface substantially coplanar with a first surface of the first die bonding layer, the method further comprising forming a wafer bonding layer on the first surface and the alignment marker surface.

Example 82 the method of clause 81, wherein the wafer bonding layer comprises: silicon and oxygen; silicon and nitrogen; or silicon, nitrogen, and carbon.

Example 83 the method of clause 80, wherein the first via and the second via further extends through the wafer bonding layer.

Example 84 the method of clause 82, further comprising attaching an interposer to the wafer bonding layer, the interposer comprising: a surface attached to the wafer bonding layer; a first interposer conductive contact attached to the first via; a second interposer conductive contact attached to the second via; a metal layer located within the interposer, the metal layer comprising a plurality of metal lines; a third via attached to the first interposer conductive contact and a first metal line of the plurality of metal lines; and a fourth via attached to the second interposer conductive contact and a second metal line of the plurality of metal lines.

Example 85 the method of clause 82, wherein the die outer lateral boundary is a first die outer lateral boundary, the alignment marker is a first alignment marker, the method further comprising attaching a structure to the first die bonding layer and the second die bonding layer, the structure comprising: a third integrated circuit die having a second die outer lateral boundary; a fourth integrated circuit die arranged laterally with and spaced laterally from the third integrated circuit die; a third die bonding layer positioned between the third integrated circuit die and the wafer bonding layer, the third die bonding layer comprising a third die conductive contact attached to the first via; a fourth die bonding layer positioned between the fourth integrated circuit die and the wafer bonding layer, the fourth die bonding layer comprising a fourth die conductive contact attached to the second via; and a second alignment marker having a second alignment marker surface substantially coplanar with the third die bonding layer, the second alignment marker located outside the second die outer lateral boundary.

Example 86 the method of clause 80, further comprising attaching an interposer to the first die bonding layer and the second die bonding layer, the interposer comprising: an interposer surface attached to the first die bonding layer and the second die bonding layer; a first interposer conductive contact on the interposer surface, the first interposer conductive contact attached to the first via; a second interposer conductive contact on the interposer surface, the second interposer conductive contact attached to the second via; a metal layer located within the interposer, the metal layer comprising a plurality of metal lines; a third via attached to the first interposer conductive contact and a first metal line of the plurality of metal lines; and a fourth via attached to the second interposer conductive contact and a second metal line of the plurality of metal lines.

Example 87 the method of clause 80, wherein the die outer lateral boundary is a first die outer lateral boundary, the alignment marker is a first alignment marker, the method further comprising attaching a structure to the first die bonding layer and the second die bonding layer, the structure comprising: a structure surface attached to the first die bonding layer and the second die bonding layer; a third integrated circuit die having a second die outer lateral boundary; a fourth integrated circuit die arranged laterally with and spaced laterally from the third integrated circuit die; a third die bonding layer positioned between the third integrated circuit die and the first die bonding layer, the third die bonding layer comprising a third via attached to the first via; a fourth die bonding layer positioned between the fourth integrated circuit die and the second die bonding layer, the fourth die bonding layer comprising a fourth via attached to the second via; and a second alignment marker having a second alignment marker surface substantially coplanar with the third die bonding layer, the second alignment marker located outside the second die outer lateral boundary.

1. An apparatus comprising:
a plurality of integrated circuit dies arranged laterally, wherein individual of the plurality of integrated circuit dies have an outer lateral boundary and physically adjacent integrated circuit dies of the plurality of integrated circuit dies are spaced laterally;
a plurality of first layers, individual of the plurality of first layers attached to a die surface of an integrated circuit die of the plurality of integrated circuit dies; and
a structure comprising one or more structure portions, individual of the one or more structure portions having a structure surface coplanar with a surface of one of the plurality of first layers, the structure positioned at least partially between physically adjacent integrated circuit dies of the plurality of integrated circuit dies.

2. The apparatus of claim 1, further comprising a second layer comprising oxygen and having a second layer outer lateral boundary, the plurality of integrated circuit dies located within the second layer outer lateral boundary, the second layer substantially filling a volume between physically adjacent integrated circuit dies of the plurality of integrated circuit dies, the structure located within the second layer outer lateral boundary.

3. The apparatus of claim 2, wherein the die surface of one of the integrated circuit die attached to one of the plurality of first layers is a first die surface, the one of the plurality of integrated circuit dies further comprising a second die surface opposite the first die surface, and the second die surface is coplanar with a surface of the second layer.

4. The apparatus of claim 1, wherein the plurality of integrated circuit dies comprise a plurality of metal lines, the structure not connected to any of the plurality of metal lines.

5. The apparatus of claim 1, further comprising:
a first die conductive contact located on the die surface of a first integrated circuit die of the plurality of integrated circuit dies;
a second die conductive contact located on the die surface of a second integrated circuit die of the plurality of integrated circuit dies;
a second layer attached to the structure and the plurality of first layers;
a first via attached to the first die conductive contact and extending through the second layer and the first layer of the plurality of first layers attached to the die surface of the first integrated circuit die; and
a second via attached to the second die conductive contact and extending through the second layer and the first layer of the plurality of first layers attached to the die surface of the second integrated circuit die.

6. The apparatus of claim 5 further comprising an interposer, the interposer comprising:
an interposer surface attached to the second layer;
a first interposer conductive contact located on the interposer surface, the first interposer conductive contact attached to the first via; and
a second interposer conductive contact located on the interposer surface, the second interposer conductive contact attached to the second via.

7. The apparatus of claim 5, wherein the plurality of integrated circuit dies is a first plurality of integrated circuit dies and the structure is a first structure having first structure portions, the apparatus further comprising a second structure comprising:
a surface attached to the second layer;
a second plurality of integrated circuit dies arranged laterally, wherein physically adjacent integrated circuit dies of the second plurality of integrated circuit dies are spaced laterally;
a plurality of third layers, individual of the plurality of third layers attached to a surface of one of the second plurality of integrated circuit dies, wherein the third layer attached to the surface of a first integrated circuit die of the second plurality of integrated circuit dies comprises a third die conductive contact and the third layer attached to the surface of a second integrated circuit die of the second plurality of integrated circuit dies comprises a fourth die conductive contact, the third die conductive contact attached to the first via, the fourth die conductive contact attached to the second via; and
a third structure having one or more third structure portions, individual of the one or more third structure portions coplanar with a surface of one of the plurality of third layers, the third structure positioned at least partially between physically adjacent integrated circuit dies of the second plurality of integrated circuit dies.

8. The apparatus of claim 1, wherein the apparatus comprises:
a first integrated circuit component comprising the plurality of integrated circuit dies, the first integrated circuit component attached to a printed circuit board; and
one or more second integrated circuit components are attached to the printed circuit board.

9. An apparatus comprising:
a plurality of integrated circuit dies arranged laterally, wherein individual of the plurality of integrated circuit dies have an outer lateral boundary and physically adjacent integrated circuit dies of the plurality of integrated circuit dies are spaced laterally;
a plurality of first layers, individual of the plurality of first layers attached to a die surface of an integrated circuit die of the plurality of integrated circuit dies;
a second layer comprising oxygen and having a second layer outer lateral boundary, the plurality of integrated circuit dies located within the second layer outer lateral boundary, the second layer substantially filling a volume between physically adjacent integrated circuit dies; and
an alignment marker having an alignment marker surface substantially coplanar with a surface of one of the plurality of first layers, the alignment marker located within the second layer outer lateral boundary and outside the outer lateral boundary of individual integrated circuit die of the plurality of integrated circuit dies.

10. The apparatus of claim 9, wherein the die surface of one the plurality of integrated circuit dies attached to one of the plurality of first layers is a first die surface, the one of the plurality of integrated circuit dies further comprising a second die surface opposite the first die surface, the first die surface substantially coplanar with a surface of the second layer.

11. The apparatus of claim 9, further comprising:
a first die conductive contact located on the die surface of a first integrated circuit die;
a second die conductive contact located on the die surface of a second integrated circuit die;
a third layer attached to the alignment marker and the plurality of first layers;
a first via attached to the first die conductive contact and extending through the second layer and the first layer of the plurality of first layers attached to the die surface of the first integrated circuit die; and
a second via attached to the second die conductive contact and extending through the second layer and the first layer of the plurality of first layers attached to the die surface of the second integrated circuit die.

12. The apparatus of claim 9, wherein the first layer of the plurality of first layers attached to the die surface of a first integrated circuit die comprises a first die conductive contact and the first layer of the plurality of first layers attached to the die surface of a second integrated circuit die comprises a second die conductive contact, the apparatus further comprising an interposer, the interposer comprising:
an interposer surface attached to the plurality of first layers;
a first interposer conductive contact located on the interposer surface, the first interposer conductive contact attached to the first die conductive contact; and
a second interposer conductive contact located on the interposer surface, the second interposer conductive contact attached to the second die conductive contact.

13. The apparatus of claim 9, wherein the plurality of integrated circuit dies is a first plurality of integrated circuit dies, the alignment marker is a first alignment marker, the apparatus further comprising:
a first die conductive contact located on the die surface of a first integrated circuit die of the first plurality of integrated circuit dies;
a second die conductive contact located on the die surface of a second integrated circuit die of the first plurality of integrated circuit dies; and
a structure comprising:
a surface attached to the plurality of first layers;
a second plurality of integrated circuit dies arranged laterally, wherein physically adjacent integrated circuit dies of the second plurality of integrated circuit dies are spaced laterally;
a plurality of third layers, individual of the plurality of third layers attached to a surface of one of the second plurality of integrated circuit dies, wherein the third layer of the plurality of third layers attached to the surface of a first integrated circuit die of the second plurality of integrated circuit dies comprises a third die conductive contact and the first layer of the plurality of first layers attached to the surface of a second integrated circuit die of the second plurality of integrated circuit dies comprises a fourth die conductive contact, the first die conductive contact attached to the third die conductive contact, the second die conductive contact attached to the fourth die conductive contact; and
a second alignment marker having a second alignment marker surface substantially coplanar with a surface of one of the plurality of third layers, the second alignment marker positioned at least partially between physically adjacent integrated circuit die of the second plurality of integrated circuit dies.

14. The apparatus of claim 9, wherein the apparatus comprises an integrated circuit component comprising the plurality of integrated circuit dies.

15. A method comprising:
forming an alignment marker on a carrier wafer; and
attaching an integrated circuit die to a surface of the carrier wafer, the integrated circuit die having a die outer lateral boundary, attaching the integrated circuit die to the surface of the carrier wafer comprising aligning the integrated circuit die to the carrier wafer in part using the alignment marker, wherein the alignment marker is located outside of the die outer lateral boundary after attachment of the integrated circuit die to the carrier wafer, wherein the integrated circuit die comprises a plurality of metal lines, the alignment marker not connected to any of the plurality of metal lines.

16. The method of claim 15, wherein the integrated circuit die is a first integrated circuit die, the method further comprising:
attaching a second integrated circuit die to the carrier wafer;
forming a first layer comprising oxygen substantially filling a volume between the first integrated circuit die and the second integrated circuit die, the first layer covering the alignment marker; and
separating the carrier wafer from the first integrated circuit die, the second integrated circuit die, and the alignment marker.

17. The method of claim 16, wherein attaching the first integrated circuit die to the carrier wafer further comprises attaching the first integrated circuit die to the carrier wafer via a first die bonding layer, the first die bonding layer positioned between the carrier wafer and a die surface of the first integrated circuit die, wherein attaching the second integrated circuit die to carrier wafer further comprises attaching the second integrated circuit die to the carrier wafer via a second die bonding layer, the second die bonding layer positioned between the carrier wafer and a die surface of the second integrated circuit die, a surface of the alignment marker substantially coplanar with a surface of the first die bonding layer.

18. The method of claim 17, the method further comprising forming a first via in the first die bonding layer and a second via in the second die bonding layer, the first via attached to a first die conductive contact located on a surface of the first integrated circuit die, the second via attached to a second die conductive contact located on a surface of the second integrated circuit die.

19. The method of claim 18, wherein the alignment marker comprises an alignment marker surface substantially coplanar with a first surface of the first die bonding layer, the method further comprising forming a wafer bonding layer on the first surface and the alignment marker surface, wherein the first via and the second via further extend through the wafer bonding layer.

20. The method of claim 18, further comprising attaching an interposer to the first die bonding layer and the second die bonding layer, the interposer comprising:
an interposer surface attached to the first die bonding layer and the second die bonding layer;
a first interposer conductive contact on the interposer surface, the first interposer conductive contact attached to the first via;
a second interposer conductive contact on the interposer surface, the second interposer conductive contact attached to the second via;
a metal layer located within the interposer, the metal layer comprising a plurality of metal lines;
a third via attached to the first interposer conductive contact and a first metal line of the plurality of metal lines; and
a fourth via attached to the second interposer conductive contact and a second metal line of the plurality of metal lines.
